(19) United States
(12) Patent Application Publication
(10) Pub. No.: US 2025/0221202 A1
(43) Pub. Date: Jul. 3, 2025

(54) DISPLAY DEVICE

(71) Applicant: LG Display Co., Ltd., Seoul (KR)

(72) Inventors: Youngsung CHO, Paju-si (KR); Jaehoon JEONG, Paju-si (KR)

(73) Assignee: LG Display Co., Ltd., Seoul (KR)

(21) Appl. No.: 18/894,808

(22) Filed: Sep. 24, 2024

(30) Foreign Application Priority Data
Dec. 28, 2023 (KR) 10-2023-0195659

(51) Int. Cl. H10K 59/131; H01L 27/12; H10K 59/121; H10K 59/65

(52) U.S. Cl. CPC H10K 59/131; H10K 59/1213; H10K 59/1216; H10K 59/65; H10D 86/421; H10D 86/60

(57) ABSTRACT

A display device according to an example of the present disclosure can include a display area having a first display area capable of transmitting light and a second display area located outside the first display area, a first pixel circuit disposed in the second display area, a first pixel electrode of a first light emitting element disposed in the first display area, and a connection line electrically connecting the first pixel electrode and the first pixel circuit.

### CROSS-REFERENCE TO RELATED APPLICATION

This application claims priority to Korean Patent Application No. 10-2023-0195659, filed in the Republic of Korea on Dec. 28, 2023, the entire contents of which is hereby expressly incorporated by reference into the present application.

### BACKGROUND

### Technical Field

Embodiments of the present disclosure relate to a display device.

### Discussion of the Related Art

As technology advances, a display device can provide shooting functions and various sensing functions in addition to image display functions. Accordingly, a display device needs to be equipped with electronic devices such as a camera and a detection sensor (which can also be referred to as a light receiving device or sensor).

Since an electronic device can receive light from the front of a display device, the electronic device needs to be installed in a location capable of receiving the light. Therefore, a camera (e.g., a camera lens) and a detection sensor need to be installed to be exposed to the front of a display device. As a result, a bezel of the display device can become larger or a camera or detection sensor can be installed in a notch or physical hole formed in a display area of the display panel.

Accordingly, as a display device is equipped with the electronic devices such as cameras and detection sensors which receive light from the front and perform a specific function, the bezel on the front of the display device can become larger or restrictions can occur in the front design of the display device.

In addition, in the case that a display device includes an electronic device, there can occur unexpected image quality deterioration depending on a structure for accommodating the electronic device.

The description provided in the background section should not be assumed to be prior art merely because it is mentioned in or associated with the background section. The background section can include information that describes one or more aspects of the subject technology.

### SUMMARY OF THE DISCLOSURE

Accordingly, the present disclosure is directed to a display device that substantially obviate one or more of the issues due to limitations and disadvantages of the related art.

An aspect of the present disclosure is to provide a display device having a light transmission structure which allows an electronic device located below a display panel to normally receive light without exposing the electronic device receiving light to the front.

Another aspect of the present disclosure is to provide a display device having a line structure capable of increasing the transmittance of areas requiring light transmission within the display area.

Yet another aspect of the present disclosure is to provide a display device with a unique connection structure between a pixel circuit and a light emitting element to increase the transmittance of areas requiring light transmission within the display area.

Additional features and aspects of the disclosure are set forth in part in the description that follows and in part will become apparent from the description or can be learned by practice of the inventive concepts provided herein. Other features and aspects of the inventive concepts can be realized and attained by the structures pointed out in the present disclosure, or derivable therefrom, and the claims hereof as well as the appended drawings.

A display device according to embodiments of the present disclosure can include a display area including a first display area capable of transmitting light, and a second display area located outside the first display area, a first pixel circuit disposed in the second display area, a first pixel electrode of a first light emitting element disposed in the first display area, and a connection line electrically connecting the first pixel electrode and the first pixel circuit.

According to one or more aspect of the present disclosure, the connection line can include a first connection line disposed in the first display area and the second display area and including a first transparent metal, and a second connection line disposed in the second display area, disposed to contact an upper surface of the first connection line, and including a first metal.

A display device according to embodiments of the present disclosure can include a substrate including a display area where an image is displayed and a non-display area where the image is not displayed, the display area including a first display area capable of transmitting light, and a second display area located outside the first display area, a first pixel circuit disposed on the substrate and in the second display area, a first pixel electrode of a first light emitting element disposed on the substrate and in the first display area, and a connection line electrically connecting the first pixel electrode and the first pixel circuit.

In the display device according to embodiments of the present disclosure, the connection line can be a single metal layer in the first display area, and can be a multiple metal layer in the second display area.

According to one or more aspect of the present disclosure, the connection line can include a first connection line disposed in the first display area and the second display area and including a first transparent metal, and a second connection line disposed in the second display area, disposed to contact an upper surface of the first connection line, and including a first metal.

According to one or more aspect of the present disclosure, the single metal layer can include the first transparent metal, and the multiple metal layers can include the first transparent metal and the first metal.

According to the embodiments of the present disclosure, there can provide a display device having a light transmission structure which allows an electronic device located below a display panel to normally receive light (e.g., visible light, infrared light, or ultraviolet light, etc.) without exposing the electronic device receiving light to the front.

According to the embodiments of the present disclosure, there can provide a display device having a line structure capable of increasing the transmittance of areas (hereinafter referred to as optical area) requiring light transmission within the display area.

According to the embodiments of the present disclosure, there can provide a display device with a unique connection structure between a pixel circuit and a light emitting element to increase the transmittance of areas requiring light transmission within the display area.

According to the embodiments of the present disclosure, there can provide a display device with reduced manufacturing costs through process optimization for forming single and multiple metal layers at once.

The effects of the present disclosure are not limited to the effects described above, and other effects not described will be clearly understood by those skilled in the art from the description below.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, that can be included to provide a further understanding of the disclosure and can be incorporated in and constitute a part of the disclosure, illustrate embodiments of the disclosure and together with the description serve to explain various principles of the disclosure.

FIGS. 1A, 1B and 1C illustrate examples of display devices according to embodiments of the present disclosure.

FIG. 2 illustrates an example of a system configuration diagram of a display device according to embodiments of the present disclosure.

FIG. 3 schematically illustrates an example of a display panel according to embodiments of the present disclosure.

FIG. 4 schematically illustrates an example of a first optical area of a first type and a normal area surrounding a first optical area in a display panel according to embodiments of the present disclosure.

FIGS. 5 and 6 illustrate an example of light emitting elements disposed in each of the first to third display areas and pixel circuits for driving the light emitting elements in a display panel according to embodiments of the present disclosure.

FIGS. 7 and 8 are plan and cross-sectional views illustrating an example of a connection structure between one first light emitting element in the first display area and one first pixel circuit in the second display area in the display panel according to embodiments of the present disclosure.

FIGS. 9 and 10 are plan and cross-sectional views illustrating an example of a connection structure between two first light emitting elements in a first display area and one first pixel circuit in a second display area in a display panel according to embodiments of the present disclosure.

FIG. 11 illustrates an example process for forming a connection line in a display panel according to embodiments of the present disclosure.

FIG. 12 illustrates an example of a layer stack of a display panel according to embodiments of the present disclosure.

FIGS. 13 to 16 illustrate examples of vertical structures in first to third display areas in a display panel according to embodiments of the present disclosure.

FIG. 17 illustrates examples of vertical structures in the first display area and the second display area of the display panel according to embodiments of the present disclosure.

FIG. 18 illustrates an example of the arrangement structure of horizontal and vertical lines in a display panel according to embodiments of the present disclosure.

FIG. 19 illustrates an example of the structure of a connection line in the first display area of a display panel according to embodiments of the present disclosure.

FIG. 20 schematically illustrates an example of a second optical area of a first type and a normal area surrounding the second optical area in a display panel according to embodiments of the present disclosure.

FIG. 21 schematically illustrates an example of a second optical area of a second type and a normal area surrounding the second optical area in a display panel according to embodiments of the present disclosure.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Hereinafter, example embodiments of the disclosure are described in detail with reference to the accompanying drawings. In assigning reference numerals to components of each drawing, the same components can be assigned the same or similar numerals even when they are shown on different drawings. When determined to make the subject matter of the disclosure unclear, the detailed description of the known art or functions can be skipped. As used herein, when a component “includes,” “has,” or “is composed of” another component, the component can add other components unless the component “only” includes, has, or is composed of” the other component. As used herein, the singular forms “a”, “an” and “the” are intended to include the plural forms as well, unless the context clearly indicates otherwise. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations can be selected only for convenience of writing the specification and can be thus different from those used in actual products.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments can be provided so that this disclosure can be sufficiently thorough and complete to assist those skilled in the art to fully understand the scope of the present disclosure. Further, the present disclosure is only defined by scopes of claims. Any implementation described herein as an “example” is not necessarily to be construed as preferred or advantageous over other implementations.

The shapes, sizes, ratios, angles, numbers, and the like, which are illustrated in the drawings to describe various example embodiments of the present disclosure are merely given by way of example. Therefore, the present disclosure is not limited to the illustrations in the drawings.

In construing an element, the element is construed as including an error range or tolerance range although there is no explicit description of such an error or tolerance range.

Such denotations as “first,” “second,” “A,” “B,” “(a),” and “(b),” can be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components can be directly “connected”, “coupled” or “linked”, or another component can intervene. Here, the other component can be included in one or more of the two or more components that are “connected”, “coupled” or “linked” to each other.

Where positional relationships are described, for example, where the positional relationship between two parts is described using “on,” “over,” “under,” “above,” “below,” “beneath,” “near,” “close to,” or “adjacent to,” “beside,” “next to,” or the like, one or more other parts can be disposed between the two parts unless a more limiting term, such as “immediate(ly),” “direct(ly),” or “close(ly)” is used. For example, when a structure is described as being positioned “on,” “over,” “under,” “above,” “below,” “beneath,” “near,” “close to,” or “adjacent to,” “beside,” or “next to” another structure, this description should be construed as including a case in which the structures contact each other as well as a case in which a third structure is disposed or interposed therebetween. Furthermore, the terms “left,” “right,” “top,” “bottom, “downward,” “upward,” “upper,” “lower,” and the like refer to an arbitrary frame of reference.

The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, or the third element.

When such terms as, e.g., “after”, “next to”, “subsequent”, and “before”, are used to describe the temporal flow relationship related to components, operation methods, and fabricating methods, it can include a non-continuous relationship unless the term such as “just”, “immediately” or “directly” is used.

When a component is designated with a value or its corresponding information (e.g., level), the value or the corresponding information can be interpreted as including a tolerance that can arise due to various factors (e.g., process factors, internal or external impacts, or noise).

Features of various embodiments of the present disclosure can be partially or overall coupled to or combined with each other, and can be variously inter-operated with each other and driven technically as those skilled in the art can sufficiently understand. Embodiments of the present disclosure can be carried out independently from each other, or can be carried out together in co-dependent relationship. Further, the term “can” fully encompasses all the meanings and coverages of the term “may.”

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art.

Hereinafter, various embodiments of the disclosure are described in detail with reference to the accompanying drawings. Further, all the components of each display device according to all embodiments of the present disclosure are operatively coupled and configured.

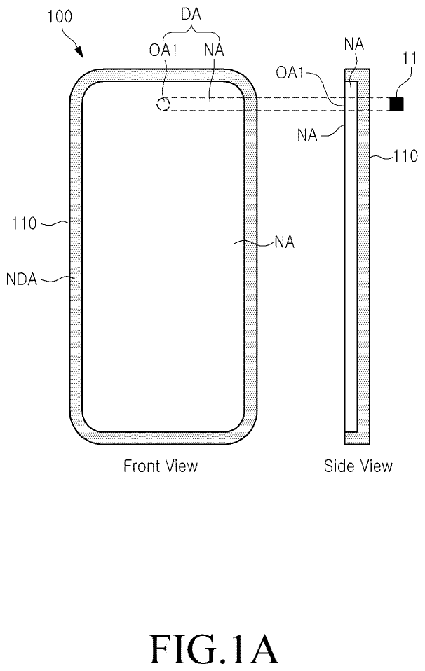

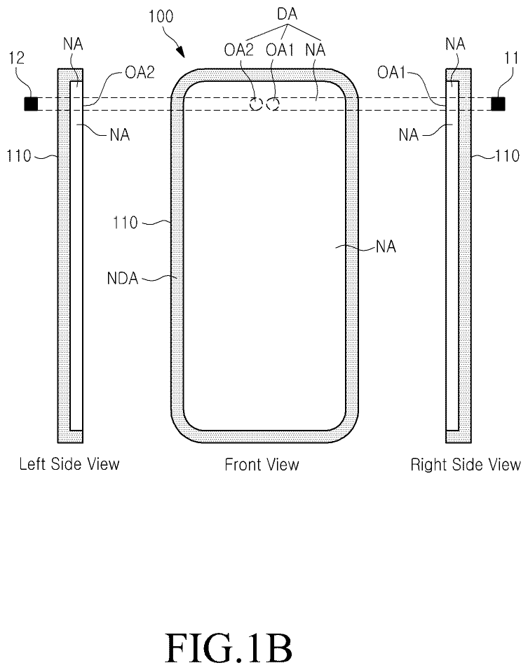

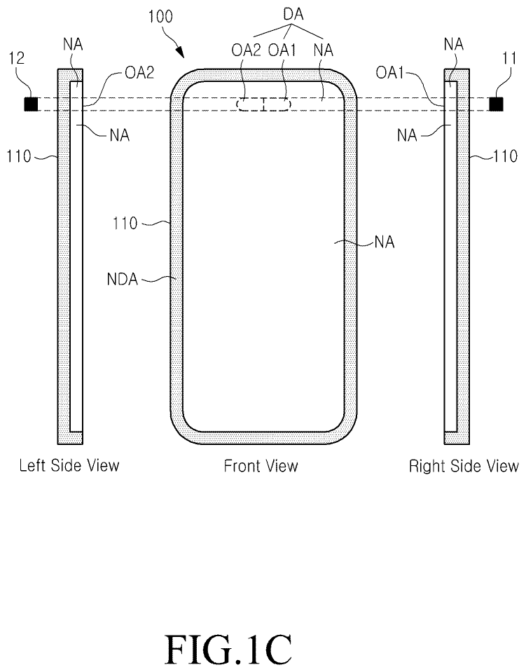

FIGS. 1A, 1B and 1C illustrate a display device 100 according to embodiments of the present disclosure.

Referring to FIGS. 1A, 1B and 1C, the display device 100 according to embodiments of the present disclosure can include a display panel 110 for displaying an image and one or more electronic devices 11 and 12.

The display panel 110 can include a display area DA (or active area) where an image is displayed and a non-display area NDA (or non-active area) where an image is not displayed.

There can be disposed a plurality of subpixels and a plurality of signal lines for driving the plurality of subpixels in the display area DA.

The non-display area NDA can be an area outside the display area DA. The non-display area NDA can surround the display area DA entirely or only in part(s). Various signal lines can be disposed in the non-display area NDA, and various driving circuits can be connected thereto. The non-display area NDA can be bent so that it is not visible from the front or can be obscured by a case. The non-display area NDA can be also referred as a bezel or a bezel area.

In the display device 100 according to embodiments of the present disclosure, one or more electronic devices 11 and 12 can be provided and installed separately from the display panel 110, and can be an electronic component located at the lower part of the display panel 110 (e.g., opposite the viewing surface).

The light can enter the front (e.g., viewing side) of the display panel 110, pass through the display panel 110, and can be delivered to one or more electronic devices 11 and 12 located below the display panel 110 (e.g., opposite the viewing surface). For example, light passing through the display panel 110 can include visible light, infrared light or ultraviolet light.

One or more electronic devices 11 and 12 can be devices which receive light passing through the display panel 110 and perform a predetermined operation using the received light. For example, the one or more electronic devices 11 and 12 can include one or more of a photographing device such as a camera (e.g., image sensor), a detection sensor such as a proximity sensor, and an illuminance sensor. Here, for example, the detection sensor can be an infrared sensor.

In the display panel 110 according to embodiments of the present disclosure, the display area DA can include a normal area NA and one or more optical areas OA1 and OA2. One or more optical areas OA1 and OA2 can be areas which overlap with one or more electronic devices 11 and 12.

According to the example of FIG. 1A, the display area DA can include a normal area NA and a first optical area OA1. Here, at least a portion of the first optical area OA1 can overlap with the first electronic device 11.

According to the example of FIG. 1B, the display area DA can include a normal area NA, a first optical area OA1, and a second optical area OA2. In the example of FIG. 1B, the normal area NA can exist between the first optical area OA1 and the second optical area OA2. Here, at least a portion of the first optical area OA1 can overlap with the first electronic device 11, and at least a portion of the second optical area OA2 can overlap with the second electronic device 12.

According to the example of FIG. 1C, the display area DA can include a normal area NA, a first optical area OA1, and a second optical area OA2. In the example of FIG. 1C, there is no normal area NA between the first optical area OA1 and the second optical area OA2. For example, the first optical area OA1 and the second optical area OA2 can be in contact with each other. Here, at least a portion of the first optical area OA1 can overlap with the first electronic device 11, and at least a portion of the second optical area OA2 can overlap with the second electronic device 12.

One or more optical areas OA1 and OA2 are required to include both an image display structure and a light transmission structure. For example, since one or more optical areas OA1 and OA2 are part of the display area DA, emission areas of subpixels for image display are required to be disposed in the one or more optical areas OA1 and OA2. Additionally, a light transmission structure is required to be formed in one or more optical areas OA1 and OA2 to transmit light to one or more electronic devices 11 and 12.

One or more electronic devices 11 and 12 are devices requiring optical reception, and can be located behind (e.g., below or opposite to the viewing surface) the display panel 110 and receive light passing through the display panel 110. One or more electronic devices 11 and 12 can be not exposed to the front (e.g., viewing side) of the display panel 110. Accordingly, when the user looks at the front of the display device 100, the electronic devices 11 and 12 can be not visible to the user.

For example, a first electronic device 11 can be a camera, and a second electronic device 12 can be a detection sensor such as a proximity sensor or illuminance sensor. For example, the detection sensor can be an infrared sensor for detecting infrared rays. Alternatively, the first electronic device 11 can be a detection sensor, and the second electronic device 12 can be a camera.

Hereinafter, for convenience of explanation, there is exemplified a case in which the first electronic device 11 is a camera and the second electronic device 12 is an infrared-based detection sensor. Here, the camera can be a camera lens or an image sensor.

In the case that the first electronic device 11 is a camera, the camera can be located behind (e.g., below) the display panel 110, but can be a front camera for photographing the front direction of the display panel 110. Accordingly, the user can view a viewing surface of the display panel 110 and take pictures or self-photographs using a camera which is not visible to the viewing surface.

The normal area NA and one or more optical areas OA1 and OA2 can be areas capable of displaying an image. However, the normal area NA can be an area in which a light transmission structure does not need to be formed, and one or more optical areas OA1 and OA2 can be areas in which a light transmission structure is required to be formed.

Therefore, one or more optical areas OA1 and OA2 are required to have transmittance above a specific level, and the normal area NA may not have light transmittance or can have low transmittance below a specific level.

For example, one or more optical areas OA1 and OA2 and the normal area NA can have different resolutions, subpixel arrangement structures, number of subpixels per unit area, electrode structures, line structures, electrode arrangement structures, or line arrangement structures etc.

For example, the number of subpixels per unit area in one or more optical areas OA1 and OA2 can be smaller than the number of subpixels per unit area in the normal area NA. For example, the resolution of one or more optical areas OA1 and OA2 can be lower than the resolution of the normal area NA. Here, the number of subpixels per unit area can mean the same as resolution, pixel density, or pixel integration. For example, a unit of the number of subpixels per unit area can be PPI (Pixels Per Inch), which means the number of pixels in 1 inch.

For example, the number of subpixels per unit area in the first optical area OA1 can be less than the number of subpixels per unit area in the normal area NA. The number of subpixels per unit area in the second optical area OA2 can be greater than or equal to the number of subpixels per unit area in the first optical area OA1, and can be less than the number of subpixels per unit area in the normal area NA.

Meanwhile, as a method to increase the transmittance of at least one of the first optical area OA1 and the second optical area OA2, there can be applied a differential pixel density design method, as described above. According to the differential pixel density design method, the display panel 110 can be designed so as for the number of subpixels per unit area of at least one of the first optical area OA1 and the second optical area OA2 to be less than the number of subpixels per unit area of the normal area NA.

However, in some cases, a differential pixel size design method can be applied as another method to increase the transmittance of at least one of the first optical area OA1 and the second optical area OA2. According to the differential pixel size design method, the display panel 110 can be designed so as for the number of subpixels per unit area of at least one of the first optical area OA1 and the second optical area OA2 to be the same as or similar to the number of subpixels per unit area of the normal area NA, but so as for a size of each subpixel SP (e.g., the size of the emission area) disposed in at least one of the first optical area OA1 and the second optical area OA2 to be smaller than the size of each subpixel SP (e.g., the size of the emission area) placed in the normal area NA.

Hereinafter, for convenience of explanation, it will be exemplified a case in which a differential pixel density design method is applied among the two methods (e.g., a differential pixel density design method and a differential pixel size design method) to increase the transmittance of at least one of the first optical area OA1 and the second optical area OA2. Accordingly, hereinafter, a small number of subpixels per unit area can correspond to a small subpixel size, and a large number of subpixels per unit area can correspond to a large subpixel size.

The first optical area OA1 can have various shapes such as circular, oval, square, hexagon, or octagon. The second optical area OA2 can have various shapes, such as circular, oval, square, hexagon, or octagon. The first optical area OA1 and the second optical area OA2 can have the same shape or different shapes.

Referring to FIG. 1C, in the case that the first optical area OA1 and the second optical area OA2 are in contact, the entire optical area including the first optical area OA1 and the second optical area OA2 can also have various shapes, such as circular, oval, square, hexagon, or octagon.

In the display device 100 according to the embodiments of the present disclosure, if the first electronic device 11, which is not exposed to the outside and is hidden at the bottom of the display panel 110, is a camera, a display device 100 according to embodiments of the present disclosure can be referred as a display device to which UDC (Under Display Camera) technology is applied.

Accordingly, in the display device 100 according to embodiments of the present disclosure, there may not be required to be formed a notch or camera hole for camera exposure in the display panel 110, so that there is no reduction in area of the display area DA. Accordingly, the size of the bezel area can be reduced, design restrictions can be eliminated, and the degree of freedom in design can be increased.

In the display device 100 according to embodiments of the present disclosure, although the one or more electronic devices 11 and 12 are hidden behind the display panel 110, the one or more electronic devices 11 and 12 are required to be able to receive light normally and normally perform a designated function thereof.

In addition, in the display device 100 according to embodiments of the present disclosure, although the one or more electronic devices 11 and 12 are hidden behind the display panel 110 and are located overlapping with the display area DA, there is required that the normal image display function is possible in one or more optical areas OA1 and OA2 overlapping with one or more electronic devices 11 and 12 in the display area DA.

Since the above-mentioned first optical area OA1 is designed as a transmission area, the image display characteristics in the first optical area OA1 can be different from those in the normal area NA.

In addition, when designing the first optical area OA1 to improve image display characteristics, there can be a possibility that the transmittance of the first optical area OA1 can decrease.

Therefore, embodiments of the present disclosure can provide a structure of the first optical area OA1 capable of preventing or reducing image quality deviation between the first optical area OA1 and the normal area NA and improving the transmittance in the first optical area OA1.

Further, embodiments of the present disclosure can provide, for the second optical area OA2 in addition to the first optical area OA1, a structure of the second optical area OA2 capable of improving the image quality in the second optical area OA2 and improving the transmittance in the second optical area OA2.

In addition, in the display device 100 according to embodiments of the present disclosure, the first optical area OA1 and the second optical area OA2 are similar in that they are light transmissive areas, but their usage examples can be different. Accordingly, in the display device 100 according to embodiments of the present disclosure, the structure of the first optical area OA1 and the structure of the second optical area OA2 can be designed differently.

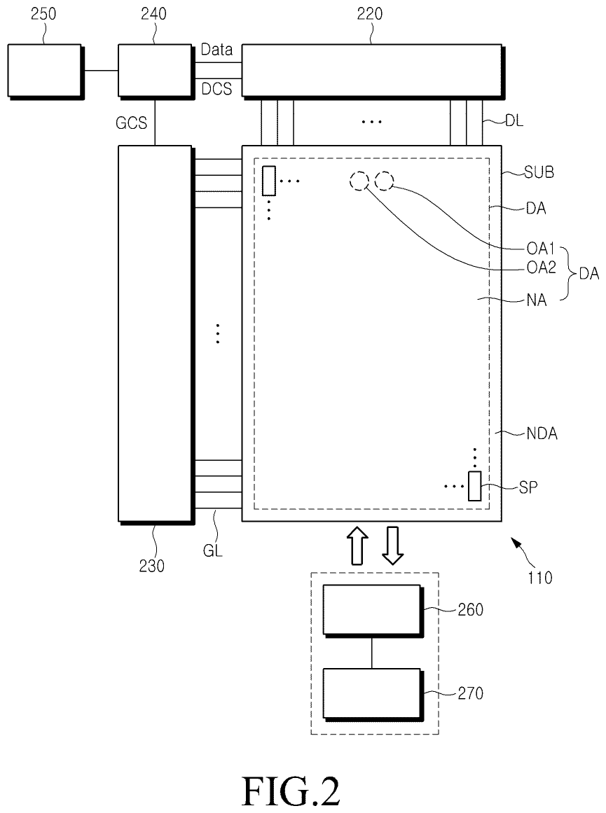

FIG. 2 illustrates a system configuration diagram of a display device 100 according to embodiments of the present disclosure.

Referring to FIG. 2, the display device 100 can include a display panel 110 and a display driving circuit as components for displaying an image.

The display driving circuit can be a circuit for driving the display panel 110, and can include a data driving circuit 220, a gate driving circuit 230 and a display controller 240.

The display panel 110 can include a display area DA for displaying an image and a non-display area NDA where an image is not displayed. The non-display area NDA can be an area outside the display area DA, and can also be referred to as a bezel area. All or part of the non-display area NDA can be an area visible from the front of the display device 100, or can be an area which is bent and not visible from the front of the display device 100.

The display panel 110 can include a substrate SUB and a plurality of subpixels SP disposed on the substrate SUB. Additionally, the display panel 110 can further include various types of signal lines to drive the plurality of subpixels SP.

The display device 100 according to embodiments of the present disclosure can be a liquid crystal display device or the like, or can be a self-luminous display device in which the display panel 110 emits light on its own. When the display device 100 according to embodiments of the present disclosure is a self-luminous display device, each of the plurality of subpixels SP can include a light emitting element. For example, the display device 100 according to embodiments of the present disclosure can be an organic light emitting display device in which a light emitting element is implemented as an organic light emitting diode (OLED). For another example, the display device 100 according to embodiments of the present disclosure can be an inorganic light emitting display device in which the light emitting element is implemented as an inorganic-based light emitting diode. For another example, the display device 100 according to embodiments of the present disclosure can be a quantum dot display device in which a light emitting element is implemented with quantum dots, which are self-luminous semiconductor crystals.

The structure of each of the plurality of subpixels SP can vary depending on the type of the display device 100. For example, if the display device 100 is a self-luminous display device in which subpixels SP emit light by themselves, each subpixel SP can include a light emitting element emitting light by itself, one or more transistors, and one or more capacitors.

For example, various types of signal lines can include a plurality of data lines DL transmitting data signals (also referred to as data voltages or image signals) and a plurality of gate lines GL transmitting gate signals (also referred to as scan signals).

The plurality of data lines DL and the plurality of gate lines GL can cross each other. Each of the plurality of data lines DL can be arranged to extend in a first direction. Each of the plurality of gate lines GL can be arranged to extend in a second direction. Here, the first direction can be a column direction and the second direction can be a row direction. Alternatively, the first direction can be a row direction and the second direction can be a column direction.

The data driving circuit 220 is a circuit for driving a plurality of data lines DL, and can output data signals to the plurality of data lines DL. The gate driving circuit 230 is a circuit for driving a plurality of gate lines GL, and can output gate signals to the plurality of gate lines GL.

The display controller 240 can be a device for controlling the data driving circuit 220 and the gate driving circuit 230, and can control the driving timing for the plurality of data lines DL and the driving timing of the plurality of gate lines GL.

The display controller 240 can supply a data driving control signal DCS to the data driving circuit 220 to control the data driving circuit 220, and can supply a gate driving control signal GCS to the gate driving circuit 230 to control the gate driving circuit 230.

The display controller 240 can receive input image data from a host system 250 and supply image data to the data driving circuit 220 based on the input image data.

The data driving circuit 220 can receive image data in digital form from the display controller 240 and convert the received image data into analog data signals to output to a plurality of data lines DL.

The gate driving circuit 230 can receive a first gate voltage corresponding to the turn-on level voltage and a second gate voltage corresponding to the turn-off level voltage along with various gate driving control signals GCS, and can generate gate signals and supply the generated gate signals to the plurality of gate lines GL.

For example, the data driving circuit 220 can be connected to the display panel 110 using a tape automated bonding (TAB) method, or can be connected to the bonding pad of the display panel 110 using a chip-on-glass (COG) or chip-on-panel (COP) method, or can be implemented using a chip-on-film (COF) method and connected to the display panel 110.

The gate driving circuit 230 can be connected to the display panel 110 using a tape automated bonding (TAB) method, or can be connected to the bonding pad of the display panel 110 using a chip-on-glass (COG) or chip-on-panel (COP) method, or can be implemented using a chip-on-film (COF) method and connected to the display panel 110. Alternatively, the gate driving circuit 230 can be a gate-in-panel (GIP) type and can be formed in the non-display area NDA of the display panel 110. The gate driving circuit 230 can be disposed on or connected to the substrate. For example, if the gate driving circuit 230 is a GIP type, the gate driving circuit 230 can be disposed in the non-display area NDA of the substrate. The gate driving circuit 230 can be connected to the substrate if the gate driving circuit 230 is a chip-on-glass (COG) type, a chip-on-film (COF) type, etc.

Meanwhile, at least one of the data driving circuit 220 and the gate driving circuit 230 can be disposed in the display area DA of the display panel 110. For example, at least one of the data driving circuit 220 and the gate driving circuit 230 can be arranged not to overlap the subpixels SP, or can be arranged to partially or entirely overlap with the subpixels SP.

The data driving circuit 220 can be connected to one side (e.g., the upper or lower side) of the display panel 110. Depending on the driving method, panel design method, etc., the data driving circuit 220 can be connected to both sides (e.g., upper and lower sides) of the display panel 110, or can be connected to two or more of the four sides of the display panel 110.

The gate driving circuit 230 can be connected to one side (e.g., left or right side) of the display panel 110. Depending on the driving method, panel design method, etc., the gate driving circuit 230 can be connected to both sides (e.g., left and right side) of the display panel 110, or can be connected to two or more of the four sides of the display panel 110.

The display controller 240 can be implemented as a separate component from the data driving circuit 220, or can be integrated with the data driving circuit 220 and implemented as an integrated circuit.

The display controller 240 can be a timing controller used in typical display technology, or can be a control device capable of further performing other control functions including a timing controller, or can be a control device different from the timing controller, or can be a control device other than a timing controller, or can be a circuit within the control device. The display controller 240 can be implemented with various circuits or electronic components, such as an integrated circuit (IC), a field programmable gate array (FPGA), an application specific integrated circuit (ASIC), or Processor.

The display controller 240 can be mounted on a printed circuit board, a flexible printed circuit, etc., and can be electrically connected to the data driving circuit 120 and the gate driving circuit 130 through a printed circuit board, a flexible printed circuit.

The display controller 240 can transmit and receive signals with the data driving circuit 220 according to one or more predetermined interfaces. For example, the interface can include a low voltage differential signaling (LVDS) interface, an embedded clock point-point interface (EPI) interface, or a serial peripheral interface (SPI).

In order to provide not only an image display function but also a touch sensing function, the display device 100 according to embodiments of the present disclosure can include a touch sensor and a touch sensing circuit for detecting an occurrence of a touch by a touch object such as a finger or pen or for detecting a touch position by sensing the touch sensor.

The touch sensing circuit can include a touch driving circuit 260 for driving and sensing a touch sensor to generate and output touch sensing data, and a touch controller 270 for detecting the occurrence of a touch or detecting the touch position using touch sensing data.

The touch sensor can include a plurality of touch electrodes. The touch sensor can further include a plurality of touch lines to electrically connect a plurality of touch electrodes and the touch driving circuit 260.

The touch sensor can exist outside the display panel 110 in the form of a touch panel or can exist inside the display panel 110. If the touch sensor exists outside the display panel 110 in the form of a touch panel, the touch sensor can be referred to as an external type. If the touch sensor is an external type, the touch panel and the display panel 110 can be manufactured separately and combined during the assembly process. The external touch panel can include a touch panel substrate and a plurality of touch electrodes on the touch panel substrate.

If the touch sensor exists inside the display panel 110, the touch sensor can be formed on the substrate SUB along with signal lines and electrodes related to display driving during the manufacturing process of the display panel 110.

The touch driving circuit 260 can supply a touch driving signal to at least one of the plurality of touch electrodes and generate touch sensing data by sensing at least one of the plurality of touch electrodes.

The touch sensing circuit can perform touch sensing using a self-capacitance sensing method or a mutual-capacitance sensing method.

If the touch sensing circuit performs touch sensing using a self-capacitance sensing method, the touch sensing circuit can perform touch sensing based on the capacitance between each touch electrode and a touch object (e.g., finger, pen, etc.). According to the self-capacitance sensing method, each of the plurality of touch electrodes can serve as a driving touch electrode and a sensing touch electrode. The touch driving circuit 260 can drive all or part of the plurality of touch electrodes and sense all or part of the plurality of touch electrodes.

If the touch sensing circuit performs touch sensing using the mutual-capacitance sensing method, the touch sensing circuit can perform touch sensing based on the capacitance between touch electrodes. According to the mutual-capacitance sensing method, the plurality of touch electrodes can be divided into driving touch electrodes and sensing touch electrodes. The touch driving circuit can drive driving touch electrodes and sense sensing touch electrodes.

The touch driving circuit 260 and the touch controller 270 included in the touch sensing circuit can be implemented as separate devices or as one device. Additionally, the touch driving circuit 260 and the data driving circuit 220 can be implemented as separate devices or as one device.

The display device 100 can further include a power supply circuit which supplies various types of power to the display driving circuit and/or the touch sensing circuit.

The display device 100 according to embodiments of the present disclosure can be a mobile terminal such as a smart phone or tablet, or a monitor or television of various sizes, but is not limited thereto, and can be a display of various types and sizes capable of displaying information or images.

As described above, in the display panel 110, the display area DA can include a normal area NA and one or more optical areas OA1 and OA2. The normal area NA and one or more optical areas OA1 and OA2 can be areas capable of displaying images. However, the normal area NA is an area in which a light transmission structure does not need to be formed, and the one or more optical areas OA1 and OA2 are areas in which a light transmission structure needs to be formed.

As described above, the display area DA in the display panel 110 can include one or more optical areas OA1 and OA2 along with the normal area NA. However, for convenience of explanation, it will be exemplified a case in which the display area DA includes both the first optical area OA1 and the second optical area OA2 (as FIGS. 1B and 1C).

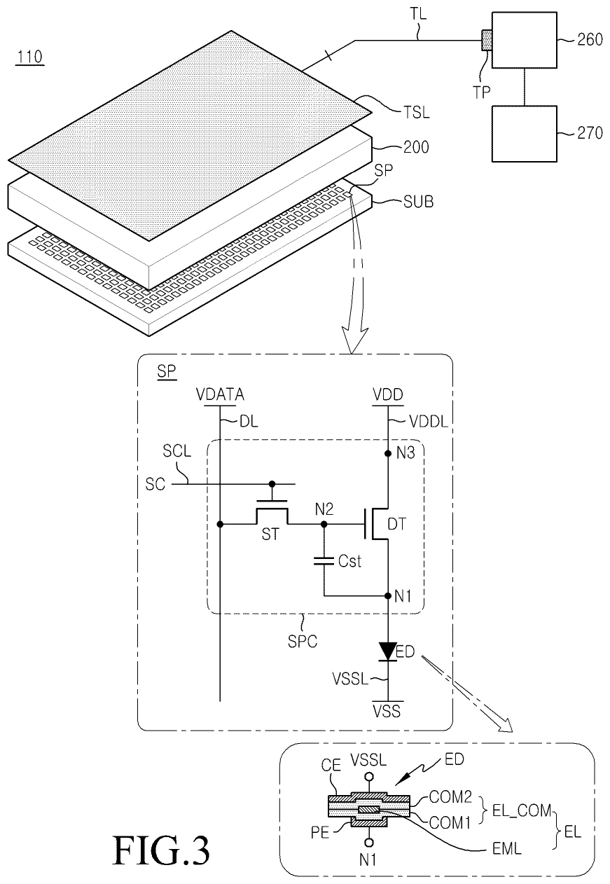

FIG. 3 schematically illustrates a display panel according to embodiments of the present disclosure.

Referring to FIG. 3, a plurality of subpixels SP can be disposed in the display area DA of the display panel 110. A plurality of subpixels SP can be disposed in the normal area NA, the first optical area OA1, and the second optical area OA2 included in the display area DA.

Each of the plurality of subpixels SP can include a light emitting element ED and a subpixel circuit SPC configured to drive the light emitting element ED.

The subpixel circuit SPC can include a driving transistor DT for driving the light emitting element ED, a scan transistor ST for transferring the data voltage Vdata to the driving transistor DT, and a storage capacitor Cst for maintaining a constant voltage during one frame.

The driving transistor DT can include a first node N1, a second node N2, and a third node N3.

The first node N1 can be a node which is electrically connected to the light emitting element ED. The second node N2 can be a node which is connected to the scan transistor ST. The third node N3 can be a node which is connected to a driving voltage line VDDL.

The first node N1 can be electrically connected to the pixel electrode PE of the light emitting element ED. The data voltage VDATA can be applied to the second node N2. A driving voltage VDD can be applied to the third node N3.

The first node N1 can be a source node or a drain node, the second node N2 can be a gate node, and the third node N3 can be a drain node or a source node. Hereinafter, for convenience of explanation, in the driving transistor DT, it will be exemplified a case in which the first node N1 is a source node, the second node N2 is a gate node, and the third node N3 is a drain node.

The light emitting element ED can include a pixel electrode PE, an intermediate layer EL, and a common electrode CE.

The pixel electrode PE can be an electrode disposed in each subpixel SP. For example, the pixel electrode PE can be electrically connected directly or indirectly (via another transistor) to the first node N1 of the driving transistor DT of each subpixel SP.

The common electrode CE can be an electrode commonly disposed in the plurality of subpixels SP. For example, the common electrode CE can be electrically connected to a base voltage line VSSL. A base voltage VSS, which is a type of common driving voltage, can be applied to the common electrode CE through the base voltage line VSSL.

For example, the pixel electrode PE can be an anode electrode, and the common electrode CE can be a cathode electrode. Alternatively, the pixel electrode PE can be a cathode electrode, and the common electrode CE can be an anode electrode. Hereinafter, for convenience of explanation, it is assumed that the pixel electrode PE is an anode electrode and the common electrode CE is a cathode electrode.

The intermediate layer EL can include an emission layer EML and a common intermediate layer EL_COM.

For example, the emission layer EML can be disposed in each of the plurality of subpixels SP. As another example, the emission layer EML can be commonly disposed in a plurality of subpixels SP.

The emission layer EML can be disposed in each emission area EA, and the common intermediate layer EL_COM can be commonly disposed over a plurality of emission areas EA and non-emission areas.

The common intermediate layer EL_COM can include a first common intermediate layer COM1 and a second common intermediate layer COM2. The first common intermediate layer COM1 can be disposed between the pixel electrode PE and the emission layer EML, and can include at least one layer (e.g., an organic layer).

For example, the first common intermediate layer COM1 can include a hole injection layer HIL and a hole transfer layer HTL. The second common intermediate layer COM2 can include an electron transport layer ETL, an electron injection layer EIL, and the like.

The hole injection layer can inject holes from the pixel electrode PE to the hole transport layer, the hole transport layer can transport holes to the emission layer EML, and the electron injection layer can inject electrons from the common electrode CE to the electron transport layer, and the electron transport layer can transport electrons to the emission layer EML.

Each light emitting element ED can include an overlapping portion of a pixel electrode PE, an emission layer EML in the intermediate layer EL, and a common electrode CE. A predetermined emission area EA can be formed by each light emitting element ED. For example, the emission area EA can be defined as an area where the pixel electrode PE, the emission layer EML in the intermediate layer EL, and the common electrode CE overlap.

For example, the light emitting element ED can be an organic light emitting diode (OLED) based on organic materials, an inorganic light emitting diode based on inorganic materials, or a quantum dot light emitting element. in the case that the light emitting element ED is an organic light emitting diode, the intermediate layer EL in the light emitting element ED can include an organic layer containing an organic material.

The scan transistor ST can be controlled on-off by a scan signal SC as a type of gate signal applied through the scan signal line SCL as a type of gate line GL, and can be electrically connected between the second node N2 of the driving transistor DT and the data line DL.

The storage capacitor Cst can be electrically connected between the first node N1 and the second node N2 of the driving transistor DT.

The subpixel circuit SPC can have a 2T-1C structure including two transistors DT and ST and one capacitor Cst, as shown in FIG. 3, but the present disclosure is not limited thereto, and can further include one or more transistors or one or more capacitors in some case. For example, 3T1C, 4T1C, 5T1C, 3T2C, 4T2C, 5T2C, 6T2C, 7T1C, 7T2C, 8T2C structures, etc. are also possible. And more or less transistors and capacitors could be included in the subpixel circuit SPC.

The storage capacitor Cst can be an external capacitor intentionally designed outside the driving transistor DT rather than a parasitic capacitor (e.g., Cgs, Cgd) as an internal capacitor which can exist between the first node N1 and the second node N2 of the driving transistor DT. Each of the driving transistor DT and the scan transistor ST can be an n-type transistor or a p-type transistor.

The circuit elements within each subpixel SP (in particular, light emitting elements EDs implemented with organic light emitting diodes (OLEDs) containing organic materials) can be vulnerable to external moisture or oxygen. Therefore, there can be disposed an encapsulation layer ENCAP on the display panel 110 to prevent or reduce oxygen from penetrating into the circuit elements (particularly, the light emitting element ED. The encapsulation layer ENCAP can be disposed to cover the light emitting elements ED.

The display device 100 according to embodiments of the present disclosure can include, in order to sense the user's touch, a touch sensor layer TSL including a plurality of sensor electrodes, a touch driving circuit 260 configured to sense a plurality of sensor electrodes, and a touch controller 270 configured to determine the presence or absence of a touch or touch coordinates using the sensing result (e.g., touch sensing data) of the touch driving circuit 260.

The touch sensor layer TSL can be embedded into the display panel 110. For example, the touch sensor layer TSL can be disposed on the encapsulation layer 200 within the display panel 110.

The display panel 110 can further include a plurality of touch pads TP electrically connected to the touch driving circuit 260, and a plurality of touch routing lines for electrically connecting a plurality of sensor electrodes included in the touch sensor layer TSL to a plurality of touch pads TP connected to the touch driving circuit 260.

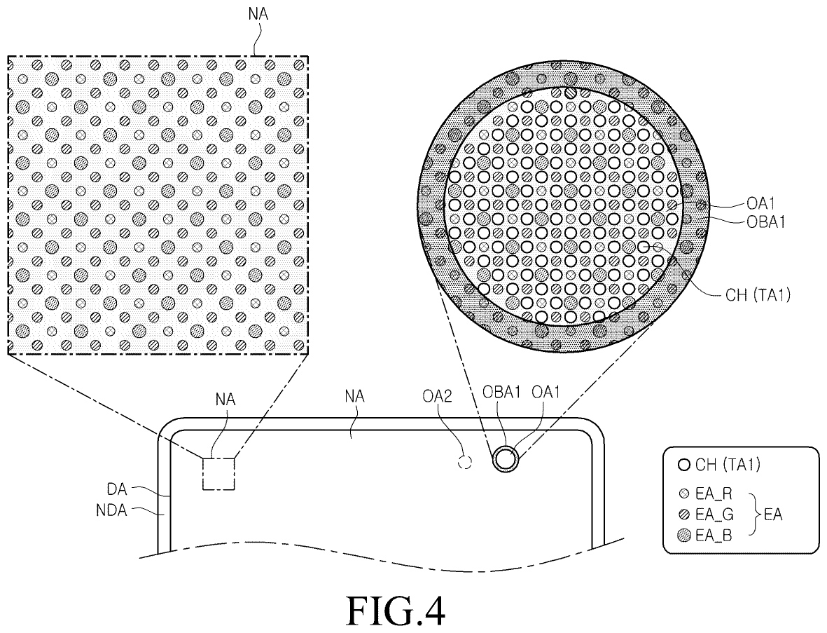

FIG. 4 schematically illustrates a first optical area OA1 of a first type and a normal area NA surrounding a first optical area in a display panel according to embodiments of the present disclosure.

Referring to FIG. 4, the display panel 110 according to embodiments of the present disclosure can include a display area DA where an image is displayed and a non-display area NDA where an image is not displayed.

The display area DA can include a transmissive first optical area OA1 and a normal area NA surrounding the first optical area OA1.

The first optical area OA1 can have a first type structure. The first optical area OA1 is of the first type can mean that a first optical bezel area OBA1 is disposed on the outside of the first optical area OA1, and the light emitting element is located in the first optical area OA1, but the pixel circuits SPC are not disposed.

In embodiments of the present disclosure, the first optical bezel area OBA1 can be considered as a part of the normal area NA.

For example, when the first optical area OA1 is the first type, the display area DA can include a first optical area OA1, a normal area NA located outside the first optical area OA1, and a first optical bezel area OBA1 which is the area between the first optical area OA1 and the normal area NA.

The first optical area OA1 can be an area that overlaps with the first electronic device 11 and is a light transmissible area through which light required for the operation of the first electronic device 11 can be transmitted.

Here, the light passing through the first optical area OA1 can include light in a single wavelength band or light in various wavelength bands. For example, light passing through the first optical area OA1 can include one or more types of light, such as visible light, infrared light, or ultraviolet light.

The first electronic device 11 can receive light passing through the first optical area OA1 and perform a predetermined operation using the received light. Here, the light that the first electronic device 11 receives through the first optical area OA1 can include at least one of visible light, infrared light, or ultraviolet light.

For example, in the case that the first electronic device 11 is a camera, light transmitted through the first optical area OA1 and utilized by the first electronic device 11 can include visible light. For another example, if the first electronic device 11 is an infrared-based sensor, the light transmitted through the first optical area OA1 and utilized by the first electronic device 11 can include infrared light (also referred to as infrared ray).

The first optical bezel area OBA1 can be an area located outside the first optical area OA1. The normal area NA can be an area located outside the first optical bezel area OBA1. The first optical bezel area OBA1 can be disposed between the first optical area OA1 and the normal area NA.

For example, the first optical bezel area OBA1 can be located only on the outer edge of a portion of the first optical area OA1, or can be disposed outside of the entire edge of the first optical area OA1.

When the first optical bezel area OBA1 is disposed outside the entire edge of the first optical area OA1, the first optical bezel area OBA1 can have a ring shape surrounding the first optical area OA1.

For example, the first optical area OA1 can have various shapes such as circular, oval, polygonal, or irregular shapes. The first optical bezel area OBA1 can have various ring shapes (e.g., a circular ring shape, an elliptical ring shape, a polygonal ring shape, or an irregular ring shape, etc.) surrounding the first optical area OA1 having various shapes.

The display area DA can include a plurality of emission areas EA. Since the first optical area OA1, the first optical bezel area OBA1, and the normal area NA are areas included in the display area DA, each of the first optical area OA1, the first optical bezel area OBA1 and the normal area NA can include a plurality of emission areas EA.

For example, the plurality of emission areas EA can include a first color emission area emitting light of a first color, a second color emission area emitting light of a second color, and a third color emission area emitting light of a third color.

At least one of the first color emission area, the second color emission area, and the third color emission area can have an area size different from the others.

The first color, the second color and the third color can be different colors and can be various colors. For example, the first color, second color, and third color can include red, green, and blue.

Hereinafter, for convenience of explanation, it will be described a case that the first color is red, the second color is green, and the third color is blue as an example, however, is not limited thereto.

If the first color is red, the second color is green, and the third color is blue, the area of a blue emission area EA_B can be the largest among the area of a red emission area EA_R, the area of the green emission area EA_G and the area of the blue emission area EA_B.

The light emitting element ED disposed in the red emission area EA_R can include an intermediate layer EL which emits red light. The light emitting element ED disposed in the green emission area EA_G can include an intermediate layer EL which emits green light. The light emitting element ED disposed in the blue emission area EA_B can include an intermediate layer EL which emits blue light.

Among the intermediate layer EL emitting red light, the intermediate layer EL emitting green light, and the intermediate layer EL emitting blue light, an organic material contained in the intermediate layer EL emitting blue light can be the most susceptible to material deterioration.

The current density supplied to the light emitting element ED disposed in the blue emission area EA_B can be the lowest by designing the area of the blue emission area EA_B to be the largest. Therefore, the degree of deterioration of a light emitting element ED disposed in the blue emission area EA_B can be similar to the degree of deterioration of a light emitting element ED disposed in the red emission area EA_R and a light emitting element ED disposed in the green emission area EA_G.

Therefore, there can be eliminated or reduced the deterioration variation between the light emitting element ED disposed in the red emission area EA_R, the light emitting element ED disposed in the green emission area EA_G and the light emitting element ED disposed in the blue emission area EA_B, thereby improving image quality. In addition, since there can be eliminated or reduced the deterioration variation between the light emitting element ED disposed in the red emission area EA_R, the light emitting element ED disposed in the green emission area EA_G and the light emitting element ED disposed in the blue emission area EA_B, there can provide an effect of reducing the lifespan variation between the light emitting element ED disposed in the red emission area EA_R, the light emitting element ED disposed in the green emission area EA_G and the light emitting element ED disposed in the blue emission area EA_B.

The first optical area OA1 is a transmissive area, and is required to have high transmittance. Accordingly, the common electrode CE can include a plurality of common electrode holes CH in the first optical area OA1. For example, in the first optical area OA1, the common electrode CE can include a plurality of common electrode holes CH.

The common electrode CE may not include the common electrode hole CH in the normal area NA. For example, in the normal area NA, the common electrode CE may not include the common electrode hole CH.

In addition, the common electrode CE may not include the common electrode hole CH in the first optical bezel area OBA1. For example, in the first optical bezel area OBA1, the common electrode CE may not include the common electrode hole CH.

In the first optical area OA1, the plurality of common electrode holes CH formed in the common electrode CE may also be referred to as a plurality of first transmission areas TA1 or a plurality of openings. Here, in FIG. 4, one common electrode hole CH has a circular shape, but a common electrode hole CH can have various shapes such as an elliptical shape, a polygonal shape, or an irregular shape in addition to the circular shape.

Further, a second optical area OA2 can be disposed adjacent to the first optical area OA1. It will be described in more detail later an arrangement of the emission areas EA in the second optical area OA2.

In the following description, for convenience of explanation, the first optical area OA1 can be referred to as a first display area OA1, and the first optical bezel area OBA1 can be referred to as a second display area OBA1. In addition, the normal area NA can be referred to as a third display area NA, and the second optical area OA2 can be referred to as a fourth display area OA2.

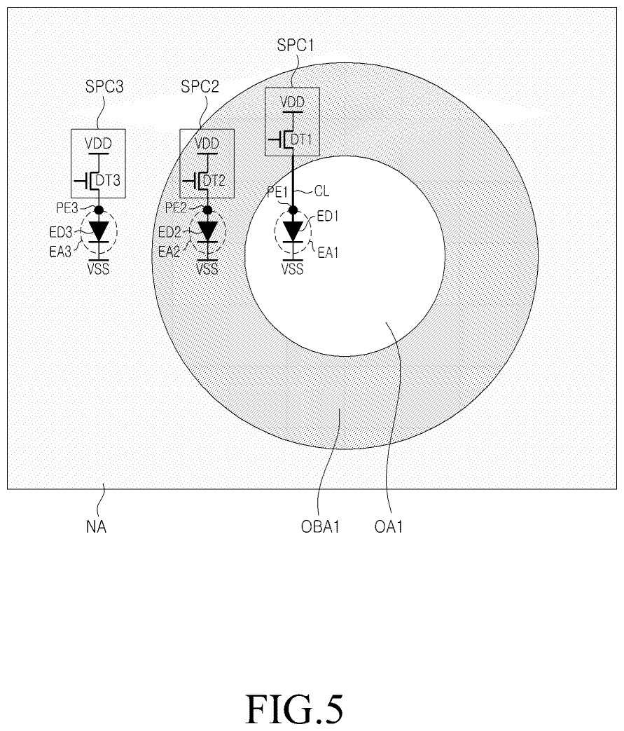

FIG. 5 illustrates first to third light emitting elements ED1, ED2 and ED3, and first to third pixel circuits SPC1, SPC2 and SPC3 for driving the first to third light emitting elements ED1, ED2 and ED3.

However, each of the first to third pixel circuits SPC1, SPC2 and SPC3 can include transistors DT and ST and a storage capacitor Cst, as shown in FIG. 3. However, for convenience of explanation, each of the pixel circuits SPC1, SPC2, SPC3 and SPC4 is briefly represented as a driving transistor DT1, DT2, DT3 and DT4.

Referring to FIG. 5, the first to third display areas OA1, OBA1 and NA can have not only positional differences but also structural differences. As a structural difference, pixel circuits SPC1, SPC2 and SPC3 can be disposed in the second display area OBA1 and the third display area NA, but no pixel circuits can be disposed in the first display area OA1. For example, the transistors DT1, DT2 and DT3 can be disposed in the second display area OBA1 and the third display area NA, but the transistors can be not disposed in the first display area OA1.

The transistors DT and ST, and storage capacitors Cst included in the pixel circuits SPC1, SPC2 and SPC3 can be components that can reduce transmittance. Accordingly, since the pixel circuits SPC1, SPC2 and SPC3 are not disposed in the first display area OA1, the transmittance of the first display area OA1 can be further increased.

The pixel circuits SPC1, SPC2 and SPC3 are disposed only in the third display area NA and the second display area OBA1, but the light emitting elements ED1, ED2 and ED3 can be disposed in all of the first to third display areas OA1, OBA1 and NA.

A first light emitting element ED1 can be disposed in the first display area OA1, but the first pixel circuit SPC1 for driving the first light emitting element ED1 may not be disposed in the first display area OA1.

The first pixel circuit SPC1 for driving the first light emitting element ED1 disposed in the first display area OA1 may not be disposed in the first display area OA1, but can be disposed in the second display area OBA1.

Hereinafter, the first to third display areas OA1, OBA1 and NA will be described in more detail.

The plurality of emission areas EA included in the display panel 110 according to embodiments of the present disclosure include a first emission area EA1, a second emission area EA2, and a third emission area EA3. Here, the first emission area EA1 can be included in the first display area OA1, the second emission area EA2 can be included in the second display area OBA1, and the third emission area EA3 can be included in the third display area NA. Hereinafter, it is assumed that the first emission area EA1, the second emission area EA2 and the third emission area EA3 are light emission areas of the same color.

The display panel 110 according to embodiments of the present disclosure can include a first light emitting element ED1 disposed in the first display area OA1 and having a first emission area EA1, a second light emitting element ED2 disposed in the second display area OBA1 and having a second emission area EA2, and a third light emitting element ED3 disposed in the third display area NA and having a third emission area EA3.

The display panel 110 according to embodiments of the present disclosure can include a first pixel circuit SPC1 configured to drive the first light emitting element ED1, a second pixel circuit SPC2 configured to drive the second light emitting element ED2, and a third pixel circuit SPC3 configured to drive the third light emitting element ED3.

The first pixel circuit SPC1 can include a first driving transistor DT1. The second pixel circuit SPC2 can include a second driving transistor DT2. The third pixel circuit SPC3 can include a third driving transistor DT3.

The first pixel circuit SPC1 can be connected to a first pixel electrode PE1 of the first light emitting element ED1, the second pixel circuit SPC2 can be connected to a second pixel electrode PE2 of the second light emitting element ED2, and the third pixel circuit SPC3 can be connected to a third pixel electrode PE3 of the third light emitting element ED3.

In the display panel 110 according to embodiments of the present disclosure, the second pixel circuit SPC2 can be disposed in the second display area OBA1 where the second light emitting element ED2 is disposed, and the third pixel circuit SPC3 can be disposed in the third display area NA where the third light emitting element ED3 is disposed.

In the display panel 110 according to embodiments of the present disclosure, the first pixel circuit SPC1 may not be disposed in the first display area OA1 where the first light emitting element ED1 is disposed, but can be disposed in the second display area OBA1 located outside the first display area OA1. Accordingly, the transmittance of the first display area OA1 can be increased.

The display panel 110 according to embodiments of the present disclosure can further include a connection line CL electrically connecting the first pixel circuit SPC1 disposed in the second display area OBA1 and the first light emitting element ED1 disposed in the first display area OA1.

The connection line CL can electrically extend the pixel electrode PE of the first light emitting element ED1 to a first node N1 of the first driving transistor DT1 in the first pixel circuit SPC1.

As described above, in the display panel 110 according to embodiments of the present disclosure, the first pixel circuit SPC1 for driving the first light emitting element ED1 disposed in the first display area OA1 can be disposed in the second display area OBA1 instead of in the first display area OA1.

In embodiments of the present disclosure, a structure connecting the pixel electrode of the first light emitting element ED1 of the first display area OA1 and the first pixel circuit SPC1 of the second display area OBA1 through the connection line CL can be referred to as a pixel electrode extension structure. In the case that the pixel electrode is an anode electrode, the pixel electrode extension structure can also be referred to as an anode extension structure.

Accordingly, the first type of the first display area OA1 can be also referred to as a “pixel electrode extension type” or “anode extension type.”

If the display panel 110 according to embodiments of the present disclosure has a pixel electrode extension structure, all or part of the connection line CL can be disposed in the first display area OA1, and the connection line CL can include a transparent line. Accordingly, even if the connection line CL is disposed in the first display area OA1, a decrease in the transmittance of the first display area OA1 can be prevented or reduced.

As described above, the first subpixel circuit SPC1 disposed in the second display area OBA1 can drive one first light emitting element ED1 disposed in the first display area OA1. This driving method and circuit connection method can be called one-to-one (1:1) driving method and one-to-one (1:1) circuit connection method. Here, in this specification, the 1:1 driving method is used in the same sense as the 1:1 circuit connection method.

Accordingly, the number of subpixel circuits disposed in the second display area OBA1 can significantly increase. The structure of the second display area OBA1 can become complicated and the aperture ratio (or light emission area) of the second display area OBA1 can decrease.

In order to increase the aperture ratio (or light emission area) of the second display area OBA1 despite having a pixel electrode extension structure (e.g., anode extension structure), the display device 100 according to embodiments of the present disclosure can have a 1:N (N is a natural number of 2 or more) driving method and a 1:N circuit connection method. Here, in this specification, the 1:N driving method can be used with the same meaning as the 1:N circuit connection method.

According to the 1:N driving method, the first subpixel circuit SPC1 disposed in the second display area OBA1 can simultaneously operate two or more light emitting elements ED1 disposed in the first display area OA1.

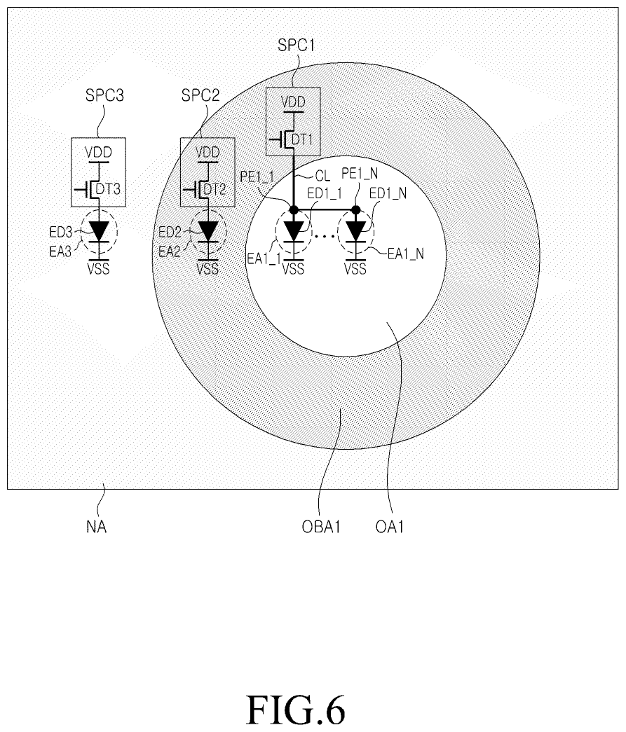

FIG. 6 illustrates the first to third light emitting elements ED1_1˜ED1_N, ED2 and ED3, and first to third subpixel circuits SPC1, SPC2 and SPC3 for driving the first to third light emitting elements ED1_1 to ED1_N, ED2 and ED3.

Referring to FIG. 6, N first light emitting elements ED1_1 to ED1_N (N is a natural number of 2 or more) arranged in the first display area OA1 can be driven by one first subpixel circuit SPC1 arranged in the second display area OBA1.

To this end, one first subpixel circuit SPC1 can be connected to N first pixel electrodes PE1_1 to PE1_N of N first light emitting elements ED1_1 to ED1_N. For example, the N first pixel electrodes PE1_1 to PE1_N of the N first light emitting elements ED1_1 to ED1_N can be electrically connected to each other.

Accordingly, although the display panel 110 has a pixel electrode extension structure (e.g., anode extension structure), the number of subpixel circuits SPC disposed in the second display area OBA1 can be reduced, thereby increasing the openings and light emission area of second display area OBA1.

Here, N first light emitting elements ED1_1 to ED1_N driven together by one first subpixel circuit SPC1 can be light emitting element which emit light of the same color, and light emitting elements which are adjacent in the row or column direction. For example, the N first light emitting elements ED1_1 to ED1_N can be driven together by one first subpixel circuit SPC1 to form N first emission areas EA1_1 to EA1_N which emit light of the same color.

The connection line CL can connect one first subpixel circuit SPC1 disposed in the second display area OBA1 to N first light emitting elements ED1_1 to ED1_N disposed in the first display area OA1.

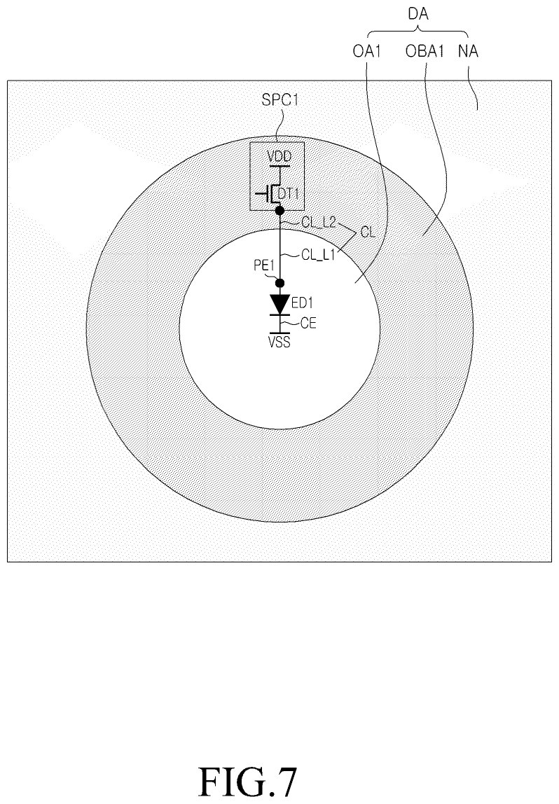

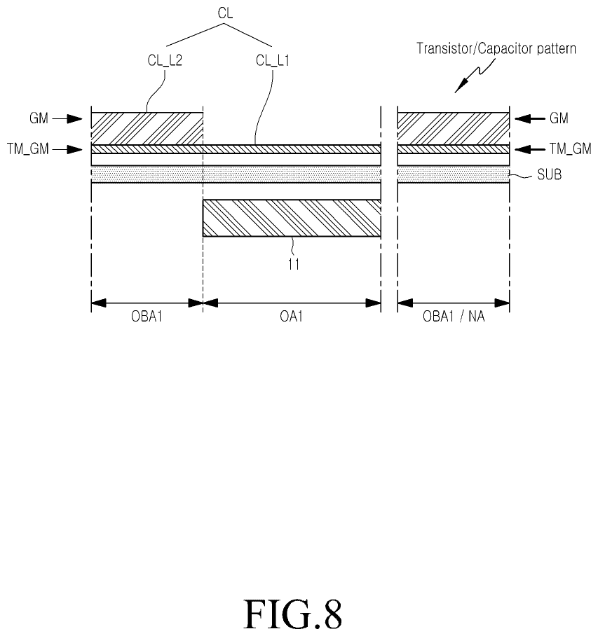

FIGS. 7 and 8 are a plan view and a cross-sectional view of a connection structure between one first light emitting element ED1 in the first display area OA1 and one first pixel circuit SPC1 in the second display area OBA1 in the display panel 110 according to embodiments of the present disclosure. However, FIGS. 7 and 8 illustrate a 1:1 driving method in which one first pixel circuit SPC1 drives one first light emitting element ED1.

Referring to FIG. 7, the display area DA of the display panel 110 according to embodiments of the present disclosure can include a first display area OA1 capable of transmitting light, a second display area OBA1 located outside the first display area OA1, and a third display area NA located outside the second display area OBA1.

The first light emitting element ED1 can be disposed in the first display area OA1, and the first pixel circuit SPC1 for driving the first light emitting element ED1 may not be disposed in the first display area OA1 but in the second display area OBA1.

The first pixel circuit SPC1 can include a first driving transistor DT1 to which a driving voltage VDD is applied. The first light emitting element ED1 can include a first pixel electrode PE1 disposed in the first display area OA1. A base voltage VSS can be applied to a common electrode CE of the first light emitting element ED1.

The display panel 110 according to embodiments of the present disclosure can include a connection line CL electrically connecting the first pixel electrode PE1 and the first pixel circuit SPC1 in order for the first pixel circuit SPC1 disposed in the second display area OBA1 to drive the first light emitting element ED1 disposed in the first display area OA1.

Referring to FIGS. 7 and 8, the connection line CL can include a first connection line CL_L1 and a second connection line CL_L2.

The first connection line CL_L1 can be disposed in the first display area OA1 and the second display area OBA1, and can include a first transparent metal TM_GM.

The second connection line CL_L2 can be disposed in the second display area OBA1, can be disposed to contact an upper surface of the first connection line CL_L1, and can include a first metal GM.

Referring to FIG. 8, the first metal GM included in the second connection line CL_L2 can be a metal included in a transistor/capacitor pattern disposed in the second display area OBA1 and the normal area NA.

The first transparent metal TM_GM included in the first connection line CL_L1 can be a transparent metal included in the transistor/capacitor pattern disposed in the second display area OBA1 and the normal area NA.

The transistor/capacitor pattern can include at least one of a source electrode, a drain electrode, and a gate electrode included in the transistor, or can include at least one of the electrodes included in the capacitor.

The first transparent metal TM_GM can be a transparent metal disposed directly below the first metal GM. For example, an upper surface of the first transparent metal TM_GM and a lower surface of the first metal GM can be in contact.

As described above, the first electronic device 11 can overlap with the first display area OA1 and can receive light passing through the first display area OA1. Light received by the first electronic device 11 can include visible light, infrared light, or ultraviolet light.

Referring to FIGS. 7 and 8, the display device 100 according to embodiments of the present disclosure can include a substrate SUB, a first light emitting element ED1, and a first pixel circuit SPC1 for driving the first light emitting element ED1.

The substrate SUB can include a display area DA where an image is displayed and a non-display area NDA where the image is not displayed.

The display area DA can include a first display area OA1 capable of transmitting light, a second display area OBA1 located outside the first display area OA1, and third display area NA located on the outside of the second display area OBA1.

The first pixel circuit SPC1 can be disposed on the substrate SUB, and can be disposed in the second display area OBA1.

The first light emitting element ED1 and the first pixel electrode PE1 included therein can be disposed on the substrate SUB, and can be disposed in the first display area OA1.

The display device 100 according to embodiments of the present disclosure can include a connection line CL electrically connecting the first pixel electrode PE1 and the first pixel circuit SPC1.

The connection line CL can be a single metal layer in the first display area OA1 and can be a multiple metal layer in the second display area OBA1.

A single metal layer can include a first transparent metal TM_GM, and a multiple metal layer can include a first transparent metal TM_GM and a first metal GM.

For example, the connection line CL can include a first connection line CL_L1 disposed in the first display area OA1 and the second display area OBA1 and including the first transparent metal TM_GM, and a second connection line CL_L2 disposed in the second display area OBA1 and in contact with the upper surface of the first connection line CL_L1 and including the first metal GM.

This corresponds to a 1:1 driving method in which one first pixel circuit SPC1 drives one first light emitting element ED1.

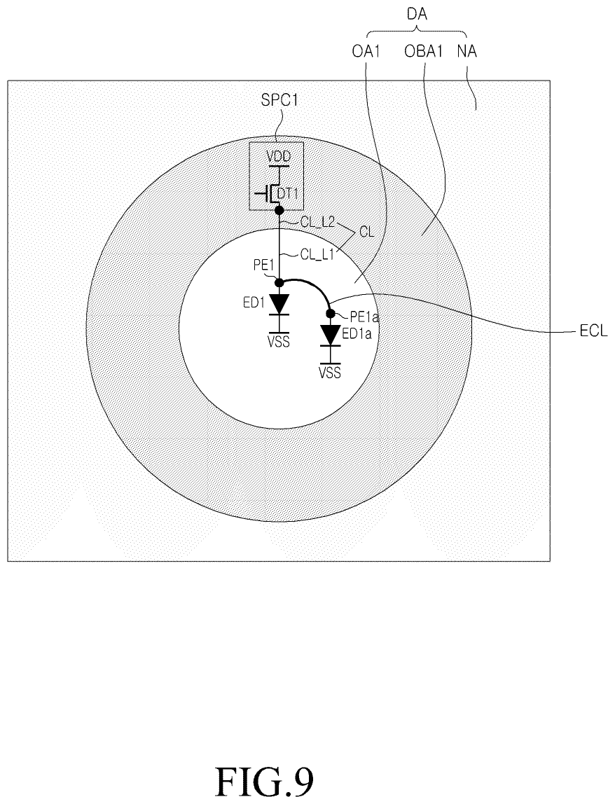

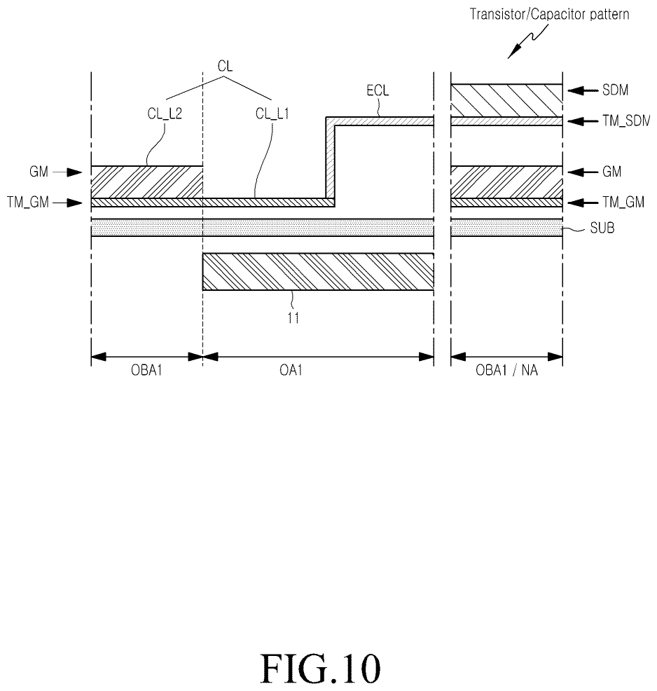

FIGS. 9 and 10 are a plan view and a cross-sectional view of a connection structure between two first light emitting elements ED1 in the first display area OA1 and one first pixel circuit SPC1 in the second display area OBA1 in the display panel 110 according to embodiments of the present disclosure. However, FIGS. 9 and 10 illustrate a 1:N (N=2) driving method in which one first pixel circuit SPC1 drives two first light emitting elements ED1.

In the following description, the description of the same content as that of FIGS. 8 and 9 will be omitted or can be briefly provided, and the description will mainly focus on the content for example different from that of FIGS. 8 and 9.

Referring to FIGS. 9 and 10, the display device 100 according to embodiments of the present disclosure can further include another first pixel electrode PE1a of another first light emitting element ED1a disposed in the first display area OA1, and an extension connection line ECL for connecting the first pixel electrode PE1 to another first pixel electrode PE1a.

The extension connection line ECL can be disposed in the first display area OA1. The extension connection line ECL can include a transparent metal, and can include a second transparent metal TM_SDM different from the first transparent metal TM_GM.

Referring to FIG. 10, the second transparent metal TM_SDM included in the extension connection line ECL can be a transparent metal included in a transistor/capacitor pattern disposed in the second display area OBA1 and the normal area NA.

The transistor/capacitor pattern can include at least one of a source electrode, a drain electrode, and a gate electrode included in the transistor, or can include at least one of the electrodes included in the capacitor.

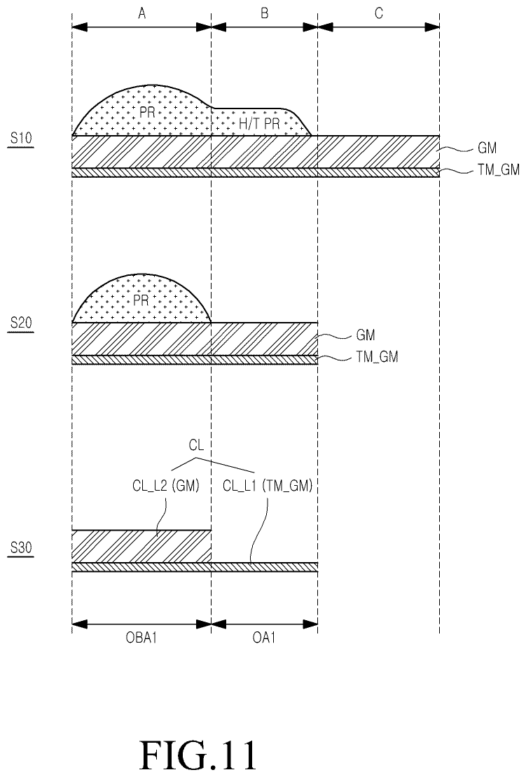

FIG. 11 illustrates a process for forming a connection line CL in a display panel 110 according to embodiments of the present disclosure.

Referring to FIG. 11, in a first step (S10), the first transparent metal TM_GM and the first metal GM can be deposited in an area A, an area B, and an area C. The first metal GM can be deposited on the first transparent metal TM_GM.

The area A can be an area where the first metal GM and the first transparent metal TM_GM remain, the area B can be an area where the first transparent metal TM_GM remains, and the area C can be an area where the first metal GM and the first transparent metal TM_GM are removed.

The area A can correspond to the second display area OBA1, and the area B can correspond to the first display area OA1.

In the first step (S10), a photoresist PR can be placed in the area A, and a halftone photoresist H/T PR can be placed in the area B.

In a second step (S20), the halftone photoresist H/T PR in the area B can be ashed, and a first etching process can be performed. During the first etching process, the first metal GM and the first transparent metal TM_GM in the area C can be etched.

In a third step (S30), the photoresist PR in the area A can be stripped, and a second etching process can be performed. During the second etching process, the first metal GM in the area B can be etched.

After the third step (S30), the first transparent metal TM_GM and the first metal GM can remain in the area A corresponding to the second display area OBA1, and only the first transparent metal TM_GM can remain in the area B corresponding the first display area OA1. Accordingly, there can be formed the connection line CL including a first connection line CL_L1 disposed in the first display area OA1 and the second display area OBA1 and including the first transparent metal TM_GM, and a second connection line CL_L2 disposed in the second display area OBA1 and in contact with the upper surface of the first connection line CL_L1 and including the first metal GM.

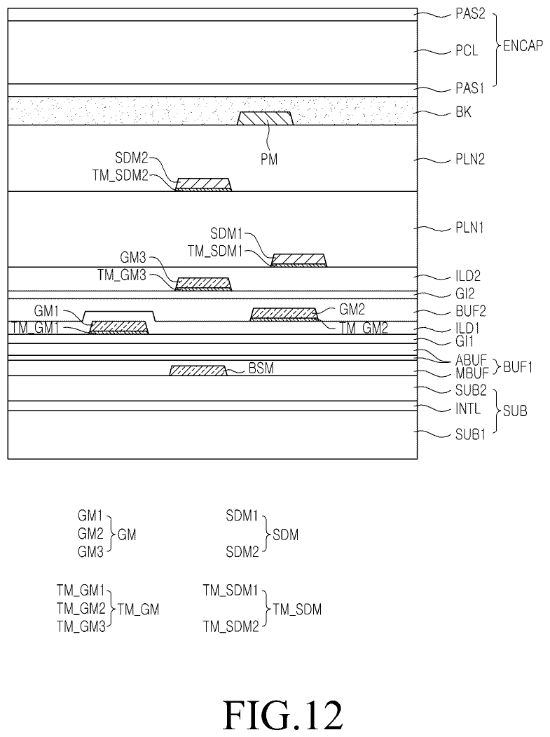

FIG. 12 illustrates a layer stack of the display panel 110 according to embodiments of the present disclosure.

The layer stack of the display panel 110 according to embodiments of the present disclosure will be described with reference to FIG. 12. The layer stack of the display panel 110 can include insulating layers (BUF1, GI1, ILD1, BUF2, GI2, ILD2, PLN1, PLN2, BK, PAS1, PCL and PAS2) with various functions, metal layers (BSM, GM1, GM2, GM3, SDM1, SDM2 and PM) with various functions, and transparent metal layers (TM_GM1, TM_GM2, TM_GM3, TM_SDM1 and TM_SDM2) with various functions. It is to be noted that the layer stack shown in FIG. 12 or FIGS. 13 to 16 (which will be described later) is provided by way of example only, and the present disclosure is not limited thereto. For example, one or more of the insulating layers, the metal layers or the transparent metal layers can be omitted or replaced with other layers or elements.

In the specification, the metal layers (BSM, GM1, GM2, GM3, SDM1, SDM2 and PM) on which the opaque metal is disposed can also be referred to as metals (BSM, GM1, GM2, GM3, SDM1, SDM2 and PM). The transparent metal layers (TM_GM1, TM_GM2, TM_GM3, TM_SDM1 and TM_SDM2) on which the transparent metal is disposed can also be referred to as transparent metal (TM_GM1, TM_GM2, TM_GM3, TM_SDM1 and TM_SDM2). In addition, the transparent metal or transparent metal described herein can also be referred to as a transparent conductive material/electrode/line/pattern, which can include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto. Similarly, the metal or opaque metal described herein can also be referred to as opaque or non-transparent conductive material/electrode/line/pattern, but the present disclosure is not limited thereto.

Referring to FIG. 12, the display panel 110 can include a substrate SUB, and the substrate SUB can include a first substrate SUB1, a substrate intermediate layer INTL, and a second substrate SUB2. Each of the first substrate SUB1 and the second substrate SUB2 can be a polyimide substrate, and the substrate intermediate layer INTL can be an inorganic layer, and can block moisture penetration.

A lower shield metal BSM can be disposed on the substrate SUB.

A first buffer layer BUF1 can be disposed on the lower shield metal BSM. The first buffer layer BUF1 can include a multi-buffer layer MBUF and an active buffer layer ABUF. A first gate insulating layer GI1 can be disposed on the first buffer layer BUF1.

A first transparent gate metal TM_GM1 and a first gate metal GM1 can be disposed on the first gate insulating layer GI1.

The first transparent gate metal TM_GM1 can be disposed on the first gate insulating layer GI1, and the first gate metal GM1 can be disposed on the first transparent gate metal TM_GM1 while contacting an upper surface of the first transparent gate metal TM_GM1.

A first interlayer insulating layer ILD1 can be disposed on the first gate metal GM1.

A second transparent gate metal TM_GM2 and a second gate metal GM2 can be disposed on the first interlayer insulating layer ILD1.

The second transparent gate metal TM_GM2 can be disposed on the first interlayer insulating layer ILD1, and the second gate metal GM2 can be disposed on the second transparent gate metal TM_GM2 while contacting an upper surface of the second transparent gate metal TM_GM2.

A second buffer layer BUF2 can be disposed on the second gate metal GM2. A second gate insulating layer GI2 can be disposed on the second buffer layer BUF2.

A third transparent gate metal TM_GM3 and a third gate metal GM3 can be disposed on the second gate insulating layer GI2.

The third transparent gate metal TM_GM3 can be disposed on the second gate insulating layer GI2, and the third gate metal GM3 can be disposed on the third transparent gate metal TM_GM3 while contacting an upper surface of the third transparent gate metal TM_GM3.

A second interlayer insulating layer ILD2 can be disposed on the third gate metal GM3.

A first transparent source-drain metal TM_SDM1 and a first source-drain metal SDM1 can be disposed on the second interlayer insulating layer ILD2.

The first transparent source-drain metal TM_SDM1 can be disposed on the second interlayer insulating layer ILD2, and the first source-drain metal SDM1 can be disposed on the first transparent source-drain metal TM_SDM1 while contacting an upper surface of the first transparent source-drain metal TM_SDM1.

A first planarization layer PLN1 can be disposed while covering the first transparent source-drain metal TM_SDM1 and the first source-drain metal SDM1.

A second transparent source-drain metal TM_SDM2 and the second source-drain metal SDM2 can be disposed on the first planarization layer PLN1.

The second transparent source-drain metal TM_SDM2 can be disposed on the first planarization layer PLN1, and the second source-drain metal SDM2 can be disposed on the second transparent source-drain metal TM_SDM2 while contacting an upper surface of the second transparent source-drain metal TM_SDM2.

A second planarization layer PLN2 can be disposed while covering the second transparent source-drain metal TM_SDM2 and the second source-drain metal SDM2.

A pixel electrode metal PM can be disposed on the second planarization layer PLN2. A bank BK can be disposed on the pixel electrode metal PM.

An encapsulation layer ENCAP can be disposed on the bank BK. The encapsulation layer ENCAP can include a first encapsulation layer PAS1, a second encapsulation layer PCL, and a third encapsulation layer PAS2. For example, the first encapsulation layer PAS1 and the third encapsulation layer PAS2 can include an inorganic layer, and the second encapsulation layer PCL can include an organic layer.

The gate metal GM can include a first gate metal GM1, a second gate metal GM2, and a third gate metal GM3. The transparent gate metal TM_GM can include a first transparent gate metal TM_GM1, a second transparent gate metal TM_GM2, and a third transparent gate metal TM_GM3.

A source-drain metal SDM can include a first source-drain metal SDM1 and a second source-drain metal SDM2. The transparent source-drain metal TM_SDM can include a first transparent source-drain metal TM_SDM1 and a second transparent source-drain metal TM_SDM2.

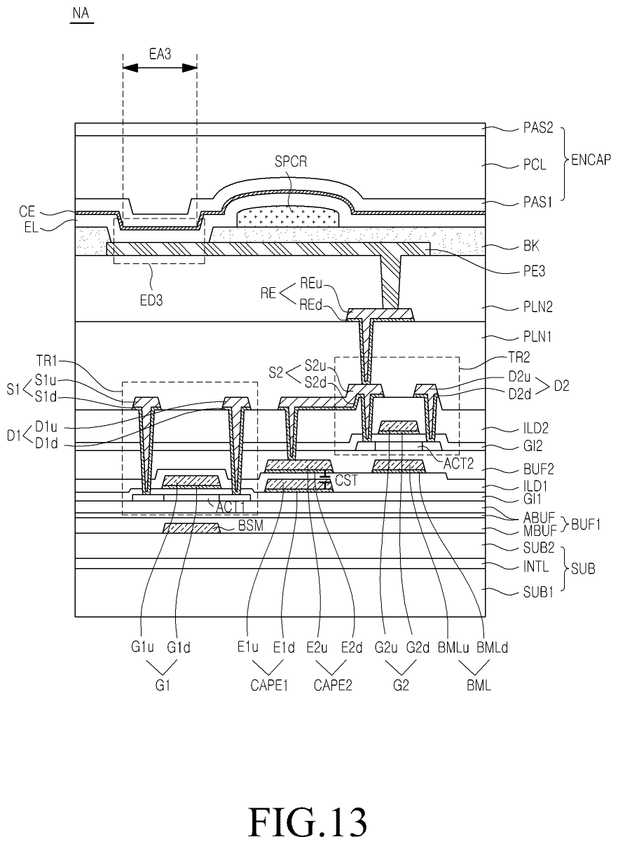

FIGS. 13 to 16 illustrate vertical structures in first to third display areas OA1, OBA1 and NA in a display panel 110 according to embodiments of the present disclosure.

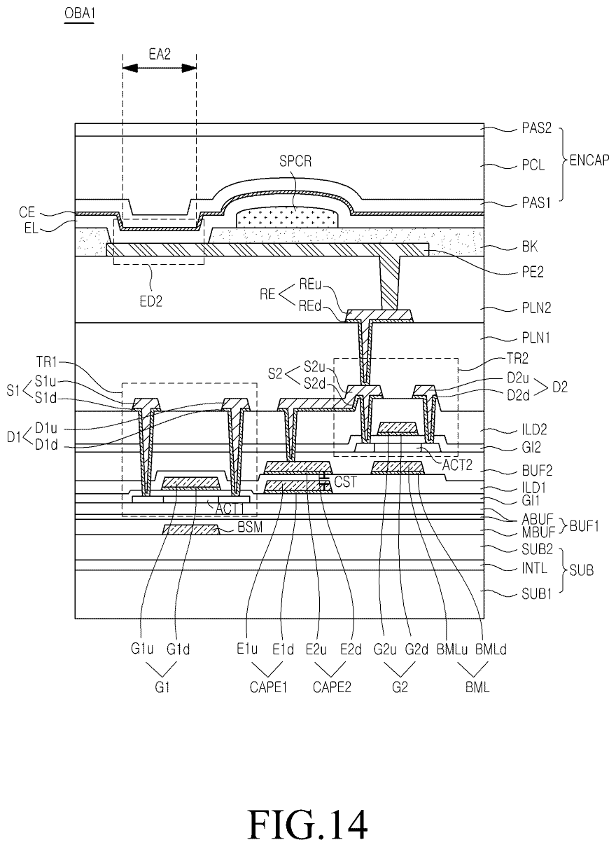

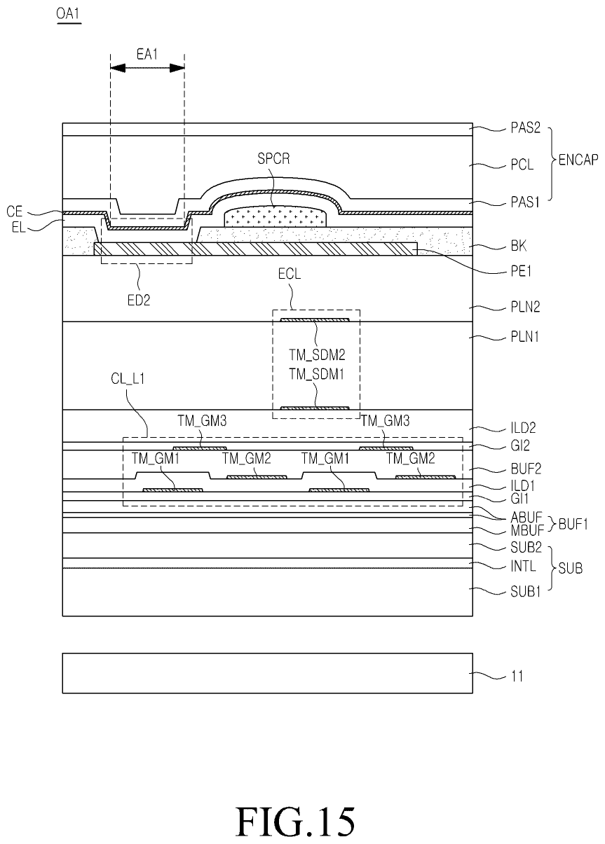

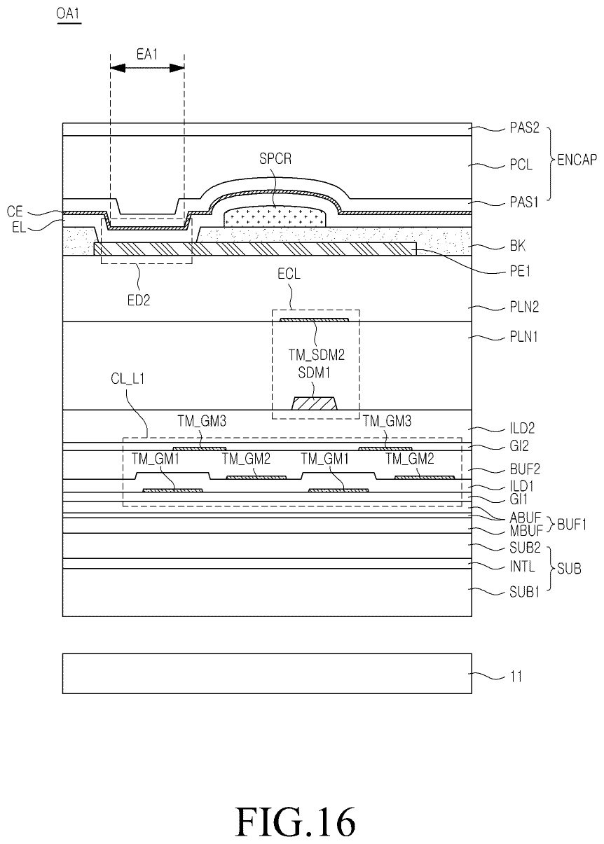

Particularly, FIGS. 13 and 14 respectively illustrate vertical structures in the third display area NA and the second display area OBA1 of the display panel 110 according to embodiments of the present disclosure, and FIGS. 15 and 16 illustrate a vertical structure in the first display area OA1 of the display panel 110 according to embodiments of the present disclosure.

In describing the vertical structure with reference to FIGS. 13 to 16, the layer stack structure in FIGS. 13 to 16 is the same as or similar to that in FIG. 12. Therefore, FIG. 12 is also referred to when describing the vertical structure with reference to FIGS. 13 to 16.

Referring to FIG. 13, the normal area NA can include a third light emitting element ED3, transistors TR1 and TR2 for driving the third light emitting element ED3, and a storage capacitor Cst.

The third light emitting element ED3 can include a third pixel electrode PE3, an intermediate layer EL and a common electrode CE, and can form a third emission area EA3.

The transistors TR1 and TR2 for driving the third light emitting element ED3 can include a first transistor TR1 and a second transistor TR2 having different active layers.

A first active layer ACT1 of the first transistor TR1 can be disposed between the first buffer layer BUF1 and the first gate insulating layer GI1, and a second active layer ACT2 of the second transistor TR2 can be disposed between the second buffer layer BUF2 and the second gate insulating layer GI2.

The first transistor TR1 can include a first active layer ACT1, a first gate electrode G1, a first source electrode S1, and a first drain electrode D1.

Each of the first gate electrode G1, the first source electrode S1 and the first drain electrode D1 can have a double electrode structure including a transparent metal and a metal.

The first gate electrode G1 can be disposed between the first gate insulating layer GI1 and the first interlayer insulating layer ILD1. The first gate electrode G1 can include a first lower gate electrode G1d including a first transparent gate metal TM_GM1 and a first upper gate electrode G1u including a first gate metal GM1.

The first source electrode S1 can be disposed between the second interlayer insulating layer ILD2 and the first planarization layer PLN1. The first source electrode S1 can include a first lower source electrode S1d including a first transparent source-drain metal TM_SDM1 and a first upper source electrode S1u including a first source-drain metal SDM1.

The first drain electrode D1 can be disposed between the second interlayer insulating layer ILD2 and the first planarization layer PLN1. The first drain electrode D1 can include a first lower drain electrode D1d including a first transparent source-drain metal TM_SDM1 and a first upper drain electrode D1u including a first source-drain metal SDM1.

The second transistor TR2 can include a second active layer ACT2, a second gate electrode G2, a second source electrode S2 and a second drain electrode D2.

Each of the second gate electrode G2, the second source electrode S2 and the second drain electrode D2 can have a double electrode structure including a transparent metal and a metal.

The second gate electrode G2 can be disposed between the second gate insulating layer GI2 and the second interlayer insulating layer ILD2. The second gate electrode G2 can include a second lower gate electrode G2d including a third transparent gate metal TM_GM3 and a second upper gate electrode G2u including a third gate metal GM3.

The second source electrode S2 can be disposed between the second interlayer insulating layer ILD2 and the first planarization layer PLN1. The second source electrode S2 can include a second lower source electrode S2d including the first transparent source-drain metal TM_SDM1 and a second upper source electrode S2u including the first source-drain metal SDM1.

The second drain electrode D2 can be disposed between the second interlayer insulating layer ILD2 and the first planarization layer PLN1. The second drain electrode D2 can include a second lower drain electrode D2d including a first transparent source-drain metal TM_SDM1 and a second upper drain electrode D2u including a first source-drain metal SDM1.

The storage capacitor Cst can include a first capacitor electrode CAPE1 and a second capacitor electrode CAPE2.

The first capacitor electrode CAPE1 can be disposed between the first gate insulating layer GI1 and the first interlayer insulating layer ILD1. The first capacitor electrode CAPE1 can include a first lower capacitor electrode E1d including the first transparent gate metal TM_GM1 and a first upper capacitor electrode E1u including the first gate metal GM1.

The second capacitor electrode CAPE2 can be disposed between the first interlayer insulating layer ILD1 and the second buffer layer BUF2. The second capacitor electrode CAPE2 can include a second lower capacitor electrode E2d including a second transparent gate metal TM_GM2 and a second upper capacitor electrode GEu including the second gate metal GM2.

The second capacitor electrode CAPE2 can be electrically connected to the second source electrode S2. An upper surface of the second upper capacitor electrode GEu can contact a lower surface of the second lower source electrode S2d.

A bottom shield metal BSM can be disposed under the first active layer ACT1 while overlapping at least a portion (e.g., channel formation area) of the first active layer ACT1.

The bottom shield metal BSM can be disposed between the substrate SUB and the first buffer layer BUF1. The bottom shield metal BSM can include a single metal layer or multiple metal layers.

A bottom metal layer BML can be disposed under the second active layer ACT2 while overlapping at least a portion (e.g., channel formation area) of the second active layer ACT2.

The bottom metal layer BML can be disposed between the first interlayer insulating layer ILD1 and the second buffer layer BUF2. The bottom metal layer BML can include a lower bottom metal layer BMLd including a second transparent gate metal TM_GM2 and an upper bottom metal layer BMLu including second gate metal GM2.

The source electrode S2 of the second transistor TR2 can be electrically connected to a third pixel electrode PE3. For example, the source electrode S2 of the second transistor TR2 can be electrically connected to the third pixel electrode PE3 through a relay electrode RE.

The relay electrode RE can have a double electrode structure including a transparent metal and a metal.

The relay electrode RE can be disposed between the first planarization layer PLN1 and the second planarization layer PLN2. The relay electrode RE can include a second lower relay electrode REd including a second transparent source-drain metal TM_SDM2 and a second upper relay electrode REu including a second source-drain metal SDM2.

A bank BK can be disposed on the third pixel electrode PE3. A spacer SPCR can be disposed on the bank BK.

An intermediate layer EL can be disposed on the bank BK. The bank BK can have an opening, and the intermediate layer EL can contact an upper surface of the third pixel electrode PE3 at the opening of the bank BK. The common electrode CE can be disposed on the intermediate layer EL.

An area where the third pixel electrode PE3, the intermediate layer EL and the common electrode CE overlap and contact each other can correspond to the opening of the bank BK and can form a third emission area EA3.

An encapsulation layer ENCAP can be disposed on the common electrode CE. A capping layer can be further disposed between the common electrode CE and the encapsulation layer ENCAP.

The encapsulation layer ENCAP can include a first encapsulation layer PAS1, a second encapsulation layer PCL and a third encapsulation layer PAS2. For example, the first encapsulation layer PAS1 and the third encapsulation layer PAS2 can include an inorganic layer, and the second encapsulation layer PCL can include an organic layer.

Referring to FIG. 14, a vertical structure of the second display area OBA1 can be basically the same as or similar to a vertical structure of the third display area NA shown in FIG. 13.

The second display area OBA1 can include a second light emitting element ED2 and transistors TR1 and TR2 for driving the second light emitting element ED2.

The second light emitting element ED2 can include a second pixel electrode PE2, an intermediate layer EL, and a common electrode CE, and can form a second emission area EA2.

The first and second transistors TR1 and TR2 for driving the second light emitting element ED2 can have the same structure as the first and second transistors TR1 and TR2 for driving the third light emitting element ED3 in FIG. 13.

In the second display area OBA1, there can be disposed the transistors for driving the first light emitting element ED1 disposed in the first display area OA1 in addition to the transistors TR1 and TR2 for driving the second light emitting element ED2 disposed in the second display area OBA1.

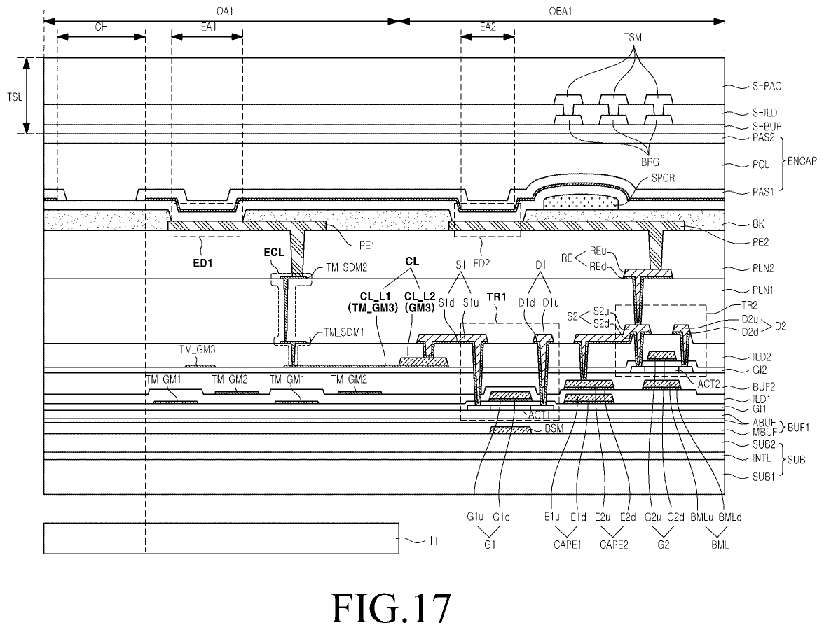

It will be described later a structure in which the transistor for driving the first light emitting element ED1 disposed in the first display area OA1 is disposed in the second display area OBA1 with reference to FIG. 17.

Referring to FIGS. 15 and 16, the first display area OA1 overlapping the first electronic device 11 can include the first light emitting element ED1.

The first light emitting element ED1 can include a first pixel electrode PE1, an intermediate layer EL, and a common electrode CE, and can form a first emission area EA1.

Among the first connection line CL_L1 and the second connection line CL_L2 included in the connection line CL, the first connection line CL_L1 disposed in the first display area OA1 can include at least one of the first transparent gate metal TM_GM1, the second transparent gate metal TM_GM2 and the third transparent gate metal TM_GM3.

For example, among the plurality of first connection lines CL_L1 included in the plurality of connection lines CL, some can include the first transparent gate metal TM_GM1, and others can include the second transparent gate metal TM_GM2, and another part can include a third transparent gate metal TM_GM3.

Referring to FIG. 15, the extension connection line ECL can include at least one of the first transparent source-drain metal TM_SDM1 and the second transparent source-drain metal TM_SDM2.

Referring to FIG. 16, the extension connection line ECL can include at least one of the first source-drain metal SDM1 and the second transparent source-drain metal TM_SDM2.

Alternatively, the extension connection line ECL can include at least one of the first transparent source-drain metal TM_SDM1 and the second source-drain metal SDM2. Alternatively, the extension connection line ECL can include at least one of the first source-drain metal SDM1 and the second source-drain metal SDM2.

Referring to FIGS. 15 and 16, the first connection line CL_L1 can be electrically connected to the first pixel electrode PE1 through the extension connection line ECL.

Meanwhile, the two first pixel electrodes PE1 disposed in the first display area OA can be electrically connected through the extension connection line ECL.

The vertical structure of each of the first to third display areas OA1, OBA1 and NA described above will be described again.

The storage capacitor Cst can be disposed in the second display area OBA1 and the third display area NA included in the display area DA, and can include a first capacitor electrode CAPE1 and a second capacitor electrode CAPE2.

The first metal GM included in the second connection line CL_L2 among the connection lines CL can include a metal GM (e.g., a first gate metal GM1 and a second gate metal GM2) included in at least one of the first capacitor electrode CAPE1 and the second capacitor electrode CAPE2.

The first capacitor electrode CAPE1 can include a first lower capacitor electrode E1d including a first transparent gate metal TM_GM1, and a first upper capacitor electrode E1u disposed to contact an upper surface of the first lower capacitor electrode E1d and including a first gate metal GM1.

The second capacitor electrode CAPE2 can include a second lower capacitor electrode E2d including a second transparent gate metal TM_GM2, and a second upper capacitor electrode E2u disposed to contact an upper surface of the second lower capacitor electrode E2d and including a second gate metal GM2.

The first transparent metal TM_GM included in the first connection line CL_L1 among the connection lines CL can include the first transparent gate metal TM_GM1 or the second transparent gate metal TM_GM2.

The first metal GM included in the second connection line CL_L2 among the connection lines CL can include the first gate metal GM1 or the second gate metal GM2.

A plurality of transistors TR1 and TR2 can be disposed in the second display area OBA1 and the third display area NA included in the display area DA, and can include gate electrodes G1 and G2, source electrodes S1 and S2, and drain electrodes D1 and D2.

The gate electrodes G1 and G2 of each of the plurality of transistors TR1 and TR2 can include a first gate metal GM1 or a third gate metal GM3.

The first metal GM included in the second connection line CL_L2 among the connection lines CL can include the first gate metal GM1 or the third gate metal GM3.

The gate electrodes G1 and G2 of each of the plurality of transistors TR1 and TR2 can include lower gate electrodes G1d and G2d and upper gate electrodes G1u and G2u.

The lower gate electrodes G1d and G2d can include the first transparent gate metal TM_GM1 or the third transparent gate metal TM_GM3.

The upper gate electrodes G1u and G2u can be disposed to contact an upper surfaces of the lower gate electrodes G1d and G2d, and can include the first gate metal GM1 or the third gate metal GM3.

The first transparent metal TM_GM included in the first connection line CL_L1 among the connection lines CL can include the first transparent gate metal TM_GM1 or the third transparent gate metal TM_GM3.

The first metal GM included in the second connection line CL_L2 among the connection lines CL can include the first gate metal GM1 or the third gate metal GM3.

The plurality of transistors TR1 and TR2 can include a first transistor TR1 which includes a first active layer ACT1 made of a silicon-based semiconductor material, and a first gate electrode G1 including a first gate metal GM1.

In this case, the first metal GM included in the second connection line CL_L2 among the connection lines CL can include the first gate metal GM1.

For example, the first active layer ACT1 can include low temperature poly silicon (LTPS), and the first transistor TR1 can be a low temperature poly silicon transistor.

The plurality of transistors TR1 and TR2 can include a second transistor TR2 which includes a second active layer ACT2 made of an oxide-based semiconductor material, and a second gate electrode G2 including a third gate metal GM3.

In this case, the first metal GM included in the second connection line CL_L2 among the connection lines CL can include the third gate metal GM3.

For example, the second active layer ACT2 can include an oxide semiconductor material, and the second transistor TR2 can be an oxide semiconductor transistor.

The first pixel circuit SPC1 and the transistors TR1 and TR2 included therein can be disposed in the second display area OBA1 and the third display area NA included in the display area DA, and can include gate electrodes G1 and G2, source electrodes S1 and S2, and drain electrodes D1 and D2.

The source electrodes S1 and S2 can include upper source electrodes S1u and S2u including a first source-drain metal SDM1, and lower source electrodes S1d and S2d disposed below the upper source electrodes S1u, S2u in contact with the upper source electrodes S1u and S2u, and including a first transparent source-drain metal TM_SDM1.

The drain electrodes D1 and D2 can include upper drain electrodes D1u and D2u including the first source-drain metal SDM1, and lower drain electrodes D1d and D2d disposed below the upper drain electrodes D1u and D2u in contact with the upper drain electrodes D1u and D2u, and including a first transparent source-drain metal TM_SDM1.

The relay electrode RE can electrically connect the second source electrode S2 or the second drain electrode D2 of the second transistor TR2 to the first pixel electrode PE1.

The relay electrode RE can include an upper relay electrode REu including the second source-drain metal SDM2, and a lower relay electrode REd disposed below the upper relay electrode REu in contact with the upper relay electrode REu and including a second transparent source-drain metal TM_SDM2.

The second transparent metal TM_SDM included in the extension connection line ECL can include the first transparent source-drain metal TM_SDM1.

Alternatively, the second transparent metal TM_SDM included in the extension connection line ECL can include a second transparent source-drain metal TM_SDM2.

FIG. 17 illustrates a vertical structure in the first display area OA1 and the second display area OBA1 of the display panel 110 according to embodiments of the present disclosure.

However, a vertical structure of the second display area OBA1 in FIG. 17 is same as or similar to a vertical structure of the second display area OBA1 in FIG. 14. A vertical structure of the first display area OA1 in FIG. 17 is same as or similar to the vertical structure of the first display area OA1 in FIG. 15. Accordingly, in the following description, it will be mainly described differences from FIGS. 14 and 15.

Referring to FIG. 17, a second light emitting element ED2 can be disposed in the second display area OBA1. The second light emitting element ED2 can include a second pixel electrode PE2, an intermediate layer EL, and a common electrode CE, and can form a second emission area EA2 at the opening of the bank BK.

A pixel circuit for driving the second light emitting element ED2 and a transistor included therein (e.g., the second transistor TR2) can be disposed in the second display area OBA1.

The first light emitting element ED1 can be disposed in the first display area OA1. The first light emitting element ED1 can include a first pixel electrode PE1, an intermediate layer EL, and a common electrode CE, and can form a first emission area EA1 at the opening of the bank BK.

A pixel circuit for driving the first light emitting element ED1 and a transistor included therein (e.g., the first transistor TR1) can be disposed in the second display area OBA1.

The connection line CL can electrically connect the first transistor TR1 disposed in the second display area OBA1 and the first pixel electrode PE1 disposed in the first display area OA1.

The connection line CL can include a first connection line CL_L1 and a second connection line CL_L2.

The first connection line CL_L1 can include a first transparent metal, and can be disposed in both the first display area OA1 and the second display area OBA1. The second connection line CL_L2 can include first metal, and can be disposed in the second display area OBA1.

The first connection line CL_L1 among the first connection line CL_L1 and the second connection line CL_L2 can be disposed in the first display area OA1. In the second display area OBA1, the second connection line CL_L2 can be disposed on the first connection line CL_L1.

The first metal included in the second connection line CL_L2 can include at least one of the first to third gate metals GM1, GM2 and GM3. The first transparent metal included in the first connection line CL_L1 can include at least one of the first to third transparent gate metals TM_GM1, TM_GM2 and TM_GM3.

According to the example of FIG. 17, the first metal included in the second connection line CL_L2 can include the third gate metal GM3. The first transparent metal included in the first connection line CL_L1 can include a third transparent gate metal TM_GM3.

A portion of the second connection line CL_L2 can be connected to the first source electrode S1 or the first drain electrode D1 of the first transistor TR1.

Another portion of the second connection line CL_L2 can be electrically connected to the first pixel electrode PE1 through the extension connection line ECL.

The extension connection line ECL can be at least one pattern that electrically connects two or more first pixel electrodes PE1 disposed in the first display area OA1 to each other.

In addition, the extension connection line ECL can be at least one pattern capable of electrically connecting at least one first pixel electrode PE1 disposed in the first display area OA1 and the connection line CL extending from the second display area OBA1 to the first display area OA1.

Referring to FIG. 17, for example, the extension connection line ECL can include a first line part including a first transparent source-drain metal TM_SDM1 and a second line part including a second transparent source-drain metal TM_SDM2.

A touch sensor layer TSL can be disposed on the encapsulation layer ENCAP.

The touch sensor layer TSL can include a sensor buffer layer S-BUF on the encapsulation layer ENCAP, a plurality of bridge metals BRG on the sensor buffer layer S-BUF, a sensor interlayer insulating layer S-ILD on the plurality of bridge metals BRG, a plurality of touch sensor metals TSM on the sensor interlayer insulating layer S-ILD, and a sensor protection layer S-PAC on the plurality of touch sensor metals TSM.

The sensor buffer layer S-BUF can be an inorganic layer or an organic layer, and can be omitted or replaced with another layer.

The sensor interlayer insulating layer S-ILD can be an inorganic layer or an organic layer.

One touch electrode (e.g., one touch sensor) can be a mesh-type electrode. Accordingly, two or more touch sensor metals TSMs among the plurality of touch sensor metals TSMs can be electrically connected to each other to form one touch electrode (e.g., one touch sensor). Two or more touch sensor metals TSM can be electrically connected to each other by a bridge metal BRG.

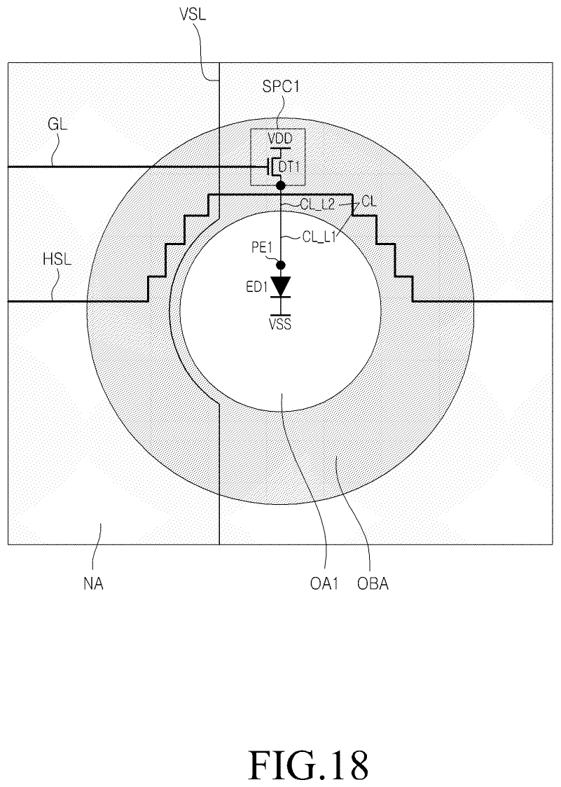

FIG. 18 illustrates the arrangement structure of a horizontal line HSL and a vertical line VSL in a display panel 110 according to embodiments of the present disclosure.

Referring to FIG. 18, various signal lines arranged on the display panel 110 according to embodiments of the present disclosure can include a horizontal line disposed in the display area DA, extending in a horizontal direction, and including horizontal line metal, and a vertical line VSL disposed in the display area DA, extending in a vertical direction, and including a vertical line metal different from the horizontal line metal.

The horizontal line HSL can include a gate line GL including a scan signal line SCL, an emission control signal line, and the like.

The horizontal line HSL can include not only the gate line GL but also power line for transmitting various direct current (DC) voltages with a constant voltage level. For example, the DC voltage can include at least one of a driving voltage VDD, an anode reset voltage (or pixel electrode reset voltage), an initialization voltage, and a bias voltage.

The vertical line VSL can include a data line DL and a connection line CL, and can further include various DC voltage line.

The horizontal line HSL and the vertical line VSL may not be disposed in the first display area OA1, but can be disposed in the second display area OBA1 and the third display area NA. In particular, the horizontal line HSL and the vertical line VSL can be disposed while bypassing the first display area OA1.

The horizontal line HSL and the vertical line VSL can intersect and overlap each other in the third display area NA and the second display area OBA1. Accordingly, the horizontal line metal of the horizontal line HSL and the vertical line metal of the vertical line VSL are required to be located in different layers.

For example, in the pixel circuit area within the second display area OBA1 and the third display area NA, the vertical line metal can include a second source-drain metal SDM2, and the horizontal line metal can include all metals (e.g., GM1, GM2, GM3, SDM1, etc.) except the second source-drain metal SDM2.

Alternatively, in the case that the vertical line VSL and the horizontal line HSL have a multi-layer line structure (e.g., double line structure including a transparent metal and a metal) including multiple metal layers, within the pixel circuit area in the second display area OBA1 and the third display area NA, the vertical line metal can include a first vertical line metal (e.g., opaque vertical line metal) and a second vertical line metal (e.g., transparent vertical line metal), and the horizontal line metal can include a first horizontal line metal (e.g., opaque horizontal line metal) and a second horizontal line metal (e.g., transparent horizontal line metal).

In this case, the first vertical line metal (e.g., opaque vertical line metal) can include a second source-drain metal SDM2, and the second vertical line metal (e.g., transparent vertical line metal) can include a second transparent source-drain metal SDM2. The first horizontal line metal (e.g., opaque horizontal line metal) can include at least one of all metals (e.g., GM1, GM2, GM3, SDM1, etc.) except the second source-drain metal SDM2, and the second horizontal line metal (e.g., transparent horizontal line metal) can include at least one of all transparent metals (e.g., TM_GM1, TM_GM2, TM_GM3, TM_SDM1, etc.) except for the second transparent source-drain metal (TM_SDM2).

For another example, in a link area (e.g., area between two adjacent pixel circuit areas) excluding the pixel circuit area in the second display area OBA1, the horizontal line metal can include at least one of a first source-drain metal SDM1 and a second source-drain metal SDM2, and the vertical line metal can include at least one of a first gate metal GM1, a second gate metal GM2 and a third gate metal GM3.

Alternatively, when the vertical line VSL and the horizontal line HSL have a multi-layer line structure (e.g., double line structure including a transparent metal and a metal) including multiple metal layers, within the link area (e.g., an area between two adjacent pixel circuit areas) excluding the pixel circuit area in the second display area OBA1, the vertical line metal can include a first vertical line metal (e.g., opaque vertical line metal) and a second vertical line metal (e.g., transparent vertical line metal), and the horizontal line metal can include a first horizontal line metal (e.g., opaque horizontal line metal) and a second horizontal line metal (e.g., transparent horizontal line metal).

In this case, the first horizontal line metal (e.g., opaque horizontal line metal) can include at least one of the first source-drain metal SDM1 and the second source-drain metal SDM2, and the second horizontal line metal (e.g., transparent horizontal line metal) can include at least one of a first transparent source-drain metal TM_SDM1 and a second transparent source-drain metal TM_SDM2. In addition, the first vertical line metal (e.g., opaque vertical line metal) can include at least one of a first gate metal GM1, a second gate metal GM2 and a third gate metal GM3, and the second vertical line metal (e.g., transparent vertical line metal) can include at least one of a first transparent gate metal TM_GM1, a second transparent gate metal TM_GM2 and a third transparent gate metal TM_GM3.

The connection line CL can be a type of vertical line VSL, and can have a partial multi-layer line structure (or partial single-layer line structure).

In more detail, the connection line CL can have a single-layer line structure including a single metal layer in the first display area OA1, and can have a multi-layer line structure including multiple metal layers in the second display area OBA1. For example, the connection line CL can include the first connection line CL_L1 in the first display area OA1, and can include the first connection line CL_L1 and the second connection line CL_L2 in the second display area OBA1.

For example, the second connection line CL_L2 can include at least one of vertical line metals. For example, the second connection line CL_L2 can include at least one of the first gate metal GM1, the second gate metal GM2 and the third gate metal GM3. The first connection line CL_L1 can include at least one of vertical line metals. For example, the first connection line CL_L1 can include at least one of the first transparent gate metal TM_GM1, the second transparent gate metal TM_GM2, and the third transparent gate metal TM_GM3.

According to the above-described example of the type of line metal, for example, according to the example of the type of horizontal line metal and vertical line metal, a layer where the first transparent metal TM_GM included in the first connection line CL_L1 is disposed can be located below a layer where the horizontal line metal (e.g., SDM1, SDM2) is disposed, and the first metal GM included in the second connection line CL_L2 can include at least one of the vertical line metals (e.g., GM1, GM2 and GM3).

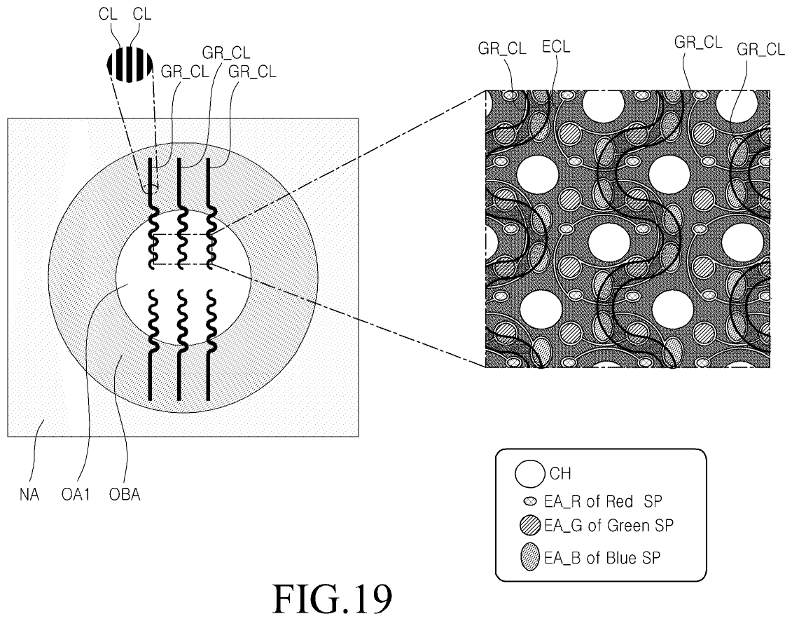

FIG. 19 illustrates the structure of a connection line CL in the first display area OA1 of a display panel 110 according to embodiments of the present disclosure.

Referring to FIG. 19, the plurality of connection lines CL can electrically connect a plurality of first pixel circuits SPC1 disposed in the second display area OBA1 and a plurality of first pixel electrodes PE1 disposed in the first display area OA1.

The plurality of connection lines CL can be tied together and arranged into one bundle GR_CL.

Further, one bundle GR_CL can be arranged in a straight shape within the second display area OBA1, but can be arranged in a curved shape or can be arranged tortuously within the first display area OA1.

Within the first display area OA1, one bundle GR_CL can be arranged tortuously while avoiding the emission areas EA_R, EA_G and EA_B, and the common electrode holes CH. The common electrode holes CH can be transmission areas or transparent areas.

Within the first display area OA1, the size of one bundle GR_CL can become smaller as the distance from the second display area OBA1 increases. For example, the farther away from the second display area OBA1, the smaller the size of the one bundle GR_CL becomes. Accordingly, when the plurality of connection lines CL are tied together and arranged into one bundle GR_CL, the optical electronic device disposed under the first display area OA can have a larger (better) value of MTF (Modulation Transfer Function) parameter than when the plurality of connection lines CL are not tied together, and the flare phenomenon can be reduced or prevented. In addition, when the bundles are arranged tortuously within the first display area OA1 or when the size of the one bundle GR_CL becomes smaller as a distance thereof from the second display area OBA1 increase, the value of MTF parameter can be further increased and the flare phenomenon can be further reduced.

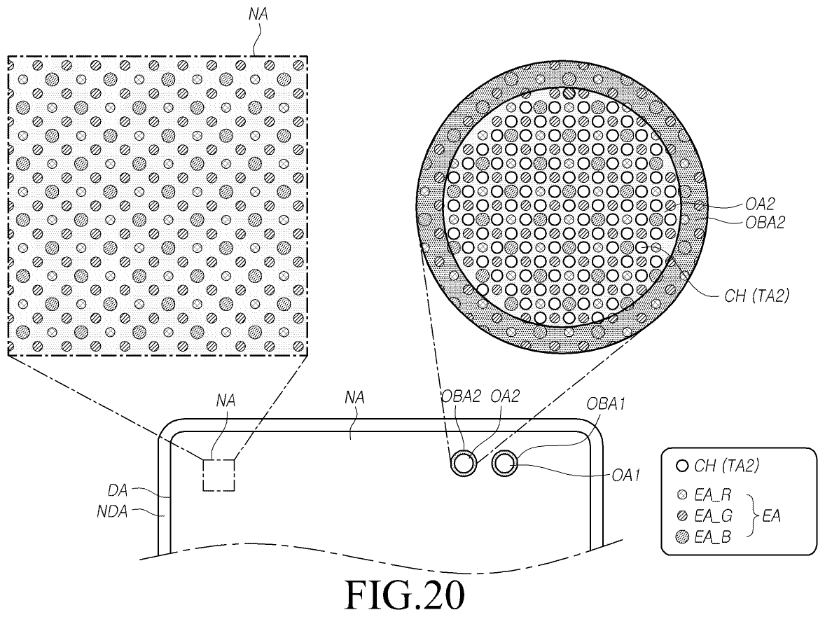

FIG. 20 schematically illustrates a second optical area OA2 of a first type and a normal area NA surrounding the second optical area in a display panel 110 according to embodiments of the present disclosure.

Referring to FIG. 20, the display area DA can further include a fourth display area OA2 and a fifth display area OBA2 which are located outside the second display area OBA1 and allow light to pass through. The fifth display area OBA2 can be located between the fourth display area OA2 and the third display area NA.

The fourth display area OA2 can be a second optical area OA2 which overlaps the second electronic device 12. The fourth display area OA2 can include a plurality of second transmission areas TA2. The plurality of second transmission areas TA2 can overlap with the plurality of common electrode holes CH formed in the common electrode CE.

The fourth display area OA2 can have a first type structure.

The fact that the fourth display area OA2 as the second optical area OA2 is of the first type can mean that a fifth display area OBA2 corresponding to the second optical bezel area OBA2 is disposed outside the fourth display area OA2, and can refer to a type in which the light emitting elements ED are disposed in the fourth display area OA2, but the pixel circuits SPC are not disposed.

The fourth display area OA2 having the first type structure can include a plurality of emission areas EA. The plurality of emission areas EA can include a plurality of red emission areas EA_R emitting red light, a plurality of green emission areas EA_G emitting green light, and a plurality of blue emission areas EA_B emitting blue light.

Two or more light emitting elements can be disposed in the fourth display area OA2 having a first type structure. Pixel circuits and transistors included therein are not disposed in the fourth display area OA2.

In addition, two or more light emitting elements can be disposed in the first display area OA1 having the first type of structure. Pixel circuits and transistors included therein are not disposed in the first display area OA1.

Pixel circuits including transistors for driving two or more light emitting elements disposed in the fourth display area OA2 can be disposed in fifth display area OBA2 rather than the fourth display area OA2.

Similarly, pixel circuits including transistors for driving two or more light emitting elements disposed in the first display area OA1 having a first type structure may not be disposed in the first display area OA1 but in the second display area OBA1.

The first electronic device 11 can overlap the first display area OA1, and can perform a first operation using the first light in the first wavelength band among the light passing through the first display area OA1.

The second electronic device 12 can overlap the fourth display area OA2, and can perform a second operation using second light in a second wavelength band different from the first wavelength band among the light transmitting through the fourth display area OA2.

In the above, the description of the first display area OA1 and the second display area OBA1, which are the first optical area OA1 and the first optical bezel area OBA1, can be equally applied to the fourth display area OA2 and the fifth display area OBA2, which are the second optical area OA2 and the second optical bezel area OBA2. However, the transmittance of the fourth display area OA2 as a second optical area OA2 can be different from the transmittance of the first display area OA1 as a first optical area OA1.

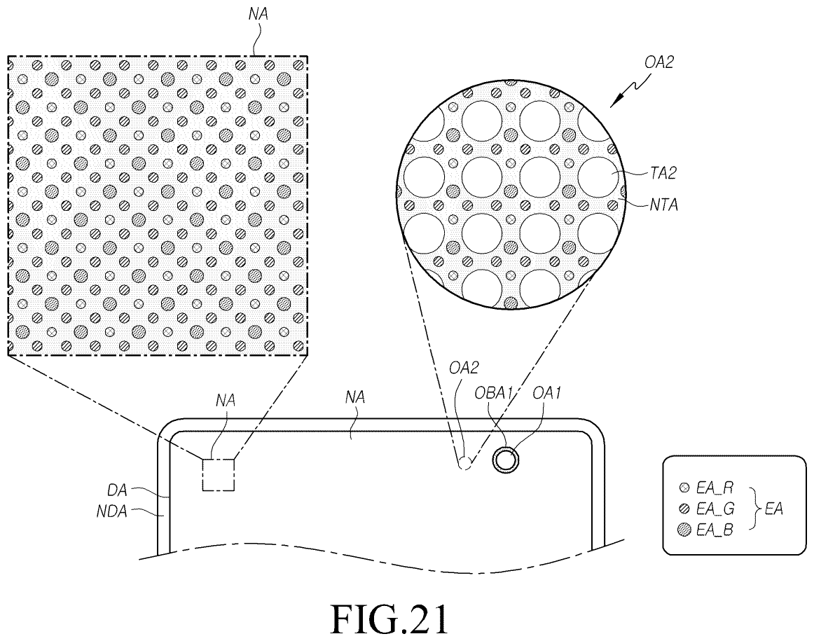

FIG. 21 schematically illustrates a second optical area of a second type and a normal area surrounding the second optical area in a display panel 110 according to embodiments of the present disclosure.

Referring to FIG. 21, the display area DA can include the fourth display area OA2, which is the second optical area OA2. When the fourth display area OA2 has a second type structure, the fourth display area OA2 can include a plurality of transmission areas TA2 and a non-transmission area NTA. Here, the second type can be also referred to as a hole type.

In the fourth display area OA2, the non-transmission area NTA can be an area excluding the plurality of transmission areas TA2.

The non-transmission area NTA can include a plurality of emission areas EA. A plurality of light emitting elements ED for a plurality of emission areas EA can be disposed in the non-transmission area NTA.

A plurality of pixel circuits SPC can be disposed in the fourth display area OA2 as the second optical area OA2. A plurality of pixel circuits SPC for driving a plurality of light emitting elements ED can be disposed in the non-transmission area NTA in the fourth display area OA2. This is different from the fact that the plurality of pixel circuits SPC are not disposed in the first display area OA1, which is the first optical area OA1 and has a first type structure.

Accordingly, the transistors DT and ST and the storage capacitors Cst can be not disposed in the first display area OA1, which is the first optical area OA1, and the transistors DT and ST and storage capacitors Cst can be disposed in the fourth display area OA4, which is the second optical area OA2.

For example, two or more light emitting elements ED can be disposed in the first display area OA1 which is the first optical area OA1, and two or more light emitting elements ED can be disposed in the non-transmission area NTA of the fourth display area OA4, which is the second optical area OA2. In comparison, transistors may not be disposed in the first display area OA1 as the first optical area OA1, and transistors can be disposed in the fourth display area OA4 as the second optical area OA2.

The arrangement of the emission areas EA in the fourth display area OA4 as the second optical area OA2 can be the same as or similar to the arrangement of the emission areas EA in the normal area NA, and can be the same as or similar to the arrangement of the emission areas EA in the first display area OA1 as the first optical area OA1.

The area size of each of the plurality of emission areas EA included in the fourth display area OA4 as the second optical area OA2 can be the same as or similar to the area size of each of the plurality of emission areas EA included in the normal area NA.

In addition, the area size of each of the plurality of emission areas EA included in the fourth display area OA4 as the second optical area OA2 can be the same as or similar to the area size of each of the plurality of emission areas EA included in the first display area OA1 as the first optical area OA1.

All or part of the first optical area OA1 can overlap with the first electronic device 11, and all or part of the second optical area OA2 can overlap with the second electronic device 12.

The transmittance of the first optical area OA1 and the second optical area OA2 can be higher than the transmittance of the normal area NA.

For example, the first optical electronic device 11 can be a camera, and the second optical electronic device 12 can be a sensor different from the camera.

For example, the first optical electronic device 11 can be a device that receives visible light and performs a specified operation, and the second optical electronic device 12 can be a device that receives light rays (e.g., infrared, ultraviolet) other than the visible light and performs a specified operation.

For example, if the first optical electronic device 11 is a device that requires a greater amount of light than the second optical electronic device 12, the transmittance of the first optical area OA1 can be greater than or equal to the transmittance of the second optical area OA2. In addition, the electronic devices or optical electronic devices described herein can also be referred to as optical sensors, optical elements or optical devices etc., and the present disclosure is not limited thereto.

The display area DA can further include a fourth display area OA2 located outside the second display area OBA1. The fourth display area OA2 can include two or more transmission areas TA2 and non-transmission areas NTA.

Hereinafter, it will be briefly described the characteristics of the first display area OA1, which is the first optical area OA1 of the first type, and the fourth display area OA2, which is the second optical area OA2 of the second type.

Two or more light emitting elements can be disposed in the first display area OA1, and two or more light emitting elements can be disposed in the fourth display area OA2.

Pixel circuits and transistors included therein may not be disposed in the first display area OA1, and pixel circuits and transistors included therein can be disposed in the fourth display area OA2.

The first electronic device 11 can overlap with the first display area OA1, and can perform a first operation using the first light in the first wavelength band among the light passing through the first display area OA1.

The second electronic device 12 can overlap with the fourth display area OA2, and can perform a second operation using second light in a second wavelength band different from the first wavelength band among the light transmitting through the fourth display area OA2.

Embodiments of the present disclosure described above are briefly described as follows.

A display device according to embodiments of the present disclosure can include a display area including a first display area capable of transmitting light, and a second display area located outside the first display area, a first pixel circuit disposed in the second display area, a first pixel electrode of a first light emitting element disposed in the first display area, and a connection line electrically connecting the first pixel electrode and the first pixel circuit.

The connection line can include a first connection line disposed in the first display area and the second display area and including a first transparent metal, and a second connection line disposed in the second display area, disposed to contact an upper surface of the first connection line, and including a first metal.

A display device according to embodiments of the present disclosure can include a substrate including a display area where an image is displayed and a non-display area where the image is not displayed, the display area including a first display area capable of transmitting light, and a second display area located outside the first display area, a first pixel circuit disposed on the substrate and in the second display area, a first pixel electrode of a first light emitting element disposed on the substrate and in the first display area, and a connection line electrically connecting the first pixel electrode and the first pixel circuit.

In the display device according to embodiments of the present disclosure, the connection line can be a single metal layer in the first display area, and can be a multiple metal layer in the second display area.

According to one or more aspects of the present disclosure, the connection line can include a first connection line disposed in the first display area and the second display area and including a first transparent metal, and a second connection line disposed in the second display area, disposed to contact an upper surface of the first connection line, and including a first metal.

According to one or more aspects of the present disclosure, the single metal layer can include the first transparent metal, and the multiple metal layers can include the first transparent metal and the first metal.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a display area including a first display area capable of transmitting light, and a second display area located outside the first display area;
a first pixel circuit disposed in the second display area;
a first pixel electrode of a first light emitting element disposed in the first display area; and
a connection line electrically connecting the first pixel electrode and the first pixel circuit,
wherein the display area further includes a third display area located outside the second display area, and
wherein the connection line comprises:
a first connection line disposed in the first display area and the second display area and including a first transparent metal, and
a second connection line disposed in the second display area, disposed to contact an upper surface of the first connection line, and including a first metal.

2. The display device of claim 1, further comprising an optical sensor overlapping with the first display area and receiving lights passing through the first display area.

3. The display device of claim 1, further comprising a common electrode commonly disposed in the first display area and the second display area,
wherein the common electrode includes one or more openings in the first display area.

4. The display device of claim 3, wherein a plurality of pixel circuits are disposed in the second display area,
wherein the connection line is formed as a plurality of connection lines electrically connecting the plurality of pixel circuits and the plurality of pixel electrodes,
wherein the plurality of connection lines are tied together and arranged into one bundle, and
wherein the one bundle is arranged tortuously while avoiding the one or more openings within the first display area.

5. The display device of claim 4, wherein a size of the one bundle becomes smaller as a distance from the second display area increases.

6. The display device of claim 1, further comprising:
a storage capacitor disposed in the second display area and including a first capacitor electrode and a second capacitor electrode,
wherein the first metal is a metal included in at least one of the first capacitor electrode and the second capacitor electrode.

7. The display device of claim 6, wherein the first capacitor electrode includes:
a first lower capacitor electrode including a first transparent gate metal; and
a first upper capacitor electrode disposed in contact with an upper surface of the first lower capacitor electrode and including a first gate metal,
wherein the second capacitor electrode includes:
a second lower capacitor electrode including a second transparent gate metal; and
a second upper capacitor electrode disposed in contact with an upper surface of the second lower capacitor electrode and including a second gate metal,
wherein the first transparent metal includes the first transparent gate metal or the second transparent gate metal, and
wherein the first metal includes the first gate metal or the second gate metal.

8. The display device of claim 1, further comprising:
a plurality of transistors disposed in the second display area and including a gate electrode, a source electrode and a drain electrode,
wherein the gate electrode includes a first gate metal or a third gate metal, and
wherein the first metal includes the first gate metal or the third gate metal.

9. The display device of claim 8, wherein the gate electrode includes:
a lower gate electrode including a first transparent gate metal or a third transparent gate metal; and
an upper gate electrode disposed in contact with an upper surface of the lower gate electrode and including the first gate metal or the third gate metal,
wherein the first transparent metal includes the first transparent gate metal or the third transparent gate metal.

10. The display device of claim 8, wherein the plurality of transistors include a first transistor including an active layer made of a silicon-based semiconductor material and a gate electrode including the first gate metal, and
wherein the first metal includes the first gate metal.

11. The display device of claim 8, wherein the plurality of transistors include a second transistor including an active layer made of an oxide-based semiconductor material and a gate electrode including the third gate metal, and
wherein the first metal includes the third gate metal.

12. The display device of claim 1, further comprising:
another pixel electrode of another light emitting element disposed in the first display area; and
an extension connection line disposed in the first display area and connecting the first pixel electrode and the another pixel electrode.

13. The display device of claim 12, wherein the extension connection line includes a second transparent metal different from the first transparent metal.

14. The display device of claim 13, wherein the first pixel circuit includes a transistor disposed in the second display area and including a gate electrode, a source electrode, and a drain electrode,
wherein the source electrode includes:
an upper source electrode including a first source-drain metal; and
a lower source electrode disposed below the upper source electrode, in contact with the upper source electrode, and including a first transparent source-drain metal,
wherein the drain electrode includes:
an upper drain electrode including the first source-drain metal; and
a lower drain electrode disposed below the upper drain electrode, in contact with the upper drain electrode, and including the first transparent source-drain metal, and
wherein the second transparent metal includes the first transparent source-drain metal.

15. The display device of claim 13, further comprising a relay electrode electrically connected with a second pixel electrode of a second light emitting element disposed in the second display area,
wherein the relay electrode includes:
an upper relay electrode including a second source-drain metal; and
a lower relay electrode disposed below the upper relay electrode, in contact with the upper relay electrode, and including a second transparent source-drain metal, and
wherein the second transparent metal includes the second transparent source-drain metal.

16. The display device of claim 1, wherein a horizontal line is disposed in the display area, extends in a first direction, and includes a horizontal line metal,
wherein a vertical line is disposed in the display area, extending in a second direction different from the first direction, and includes a vertical line metal different from the horizontal line metal, and
wherein a layer on which the first transparent metal is disposed is located below a layer on which the horizontal wiring metal is disposed.

17. The display device of claim 1, wherein a horizontal line is disposed in the display area, extends in a first direction, and includes horizontal line metal,
wherein a vertical line is disposed in the display area, extending in a second direction different from the first direction, and includes a vertical line metal different from the horizontal line metal, and
wherein the first metal includes the vertical line metal.

18. The display device of claim 16, wherein the horizontal line and the vertical line are disposed while bypassing the first display area.

19. A display device comprising:
a substrate including a display area configured to display an image and a non-display area configured to not display an image, the display area including a first display area capable of transmitting light and a second display area located outside the first display area;
a first pixel circuit disposed on the substrate and in the second display area;
a first pixel electrode of a first light emitting element disposed on the substrate and in the first display area; and
a connection line electrically connecting the first pixel electrode and the first pixel circuit,
wherein the connection line is a single metal layer in the first display area, and is a multiple metal layer in the second display area.

20. The display device of claim 19, wherein the connection line comprises:
a first connection line disposed in the first display area and the second display area and including a first transparent metal, and
a second connection line disposed in the second display area, disposed to contact an upper surface of the first connection line, and including a first metal,
wherein the single metal layer includes the first transparent metal, and
wherein the multi metal layer includes both the first transparent metal and the first metal.
